(19) United States
(12) Patent Application Publication
(10) Pub. No.: US 2018/0188290 A1
(43) Pub. Date: Jul. 5, 2018

(54) TEST SOCKET, TEST SOCKET MANUFACTURING METHOD, AND JIG ASSEMBLY FOR TEST SOCKET

(71) Applicant: OKINS ELECTRONICS CO.,LTD, Gyeonggi-do (KR)

(72) Inventors: Sung Gye PARK, Gyeonggi-do (KR); Jin Kook JUN, Gyeonggi-do (KR)

(73) Assignee: OKINS ELECTRONICS CO.,LTD, Gyeonggi-do (KR)

(21) Appl. No.: 15/741,213

(22) PCT Filed: Jul. 4, 2016
(86) PCT No.: PCT/KR2016/007183

§ 371 Date: Feb. 23, 2018

(30) Foreign Application Priority Data
Jul. 3, 2015 (KR) 10-2015-0095483
Oct. 16, 2015 (KR) 10-2015-0144949
Oct. 16, 2015 (KR) 10-2015-0144953
Oct. 16, 2015 (KR) 10-2015-0144955
Oct. 16, 2015 (KR) 10-2015-0144958
Oct. 16, 2015 (KR) 10-2015-0144959
Oct. 16, 2015 (KR) 10-2015-0144960
Dec. 17, 2015 (KR) 10-2015-0181170
Mar. 18, 2016 (KR) 10-2016-0032581

(51) Int. Cl. G01R 3/00; G01R 1/04; G01R 31/28; H05K 3/10; H05K 3/28; H05K 1/11; H05K 1/02; H05K 3/40

(52) U.S. Cl. CPC G01R 3/00; H05K 2203/041; G01R 31/2896; H05K 3/103; H05K 3/285; H05K 1/111; H05K 1/028; H05K 3/4007; H05K 1/0268; H05K 2203/1327; H05K 2201/10287; H05K 2201/0154; H05K 2201/09827; H05K 2203/166; H05K 2201/10234; H05K 2201/0162; G01R 1/0433

(57) ABSTRACT

A method of manufacturing a test socket includes preparing a printed circuit board (PCB) on which a bonding pad is disposed, bonding a conductive wire on the bonding pad, mounting, on an upper surface of the PCB, a space through which the bonding pad is exposed, mounting, on an upper surface of the space, a base through which the bonding pad is exposed, mounting, on an upper surface of the base, a jig which covers the bonding pad, and injecting a liquid silicone rubber into a jig assembly by using the jig assembly as a mold, the jig assembly including the PCB, the space, the base, and the jig.

### TECHNICAL FIELD

The present disclosure relates to a test socket, a manufacturing method thereof, and an assembly for manufacturing the same, and more particularly, to a test socket for testing electrical characteristics of a semiconductor device manufactured through a semiconductor package manufacturing process before the semiconductor device is shipped, and a method of manufacturing the test socket.

### BACKGROUND ART

Generally, characteristics and a defective condition of a semiconductor device manufactured through a complicated process are tested through various electrical tests.

Specifically, in an electrical test for a semiconductor device such as a semiconductor integrated circuit (IC) device including a package IC and a multi-chip module (MCM) and a wafer on which an IC is formed, a test socket is disposed between the semiconductor device and a test device for a terminal formed at one side surface of the semiconductor device, which is a subject to be tested, and a pad of the test device to come into electrical contact with each other.

However, the test socket includes a conductive connector (a wire, a spring, or the like) for coming into contact with terminals disposed at the test device.

The conductive connector should be able to absorb an impact upon contact with the semiconductor device. When a flexible printed circuit board (FPCB) is used as a base substrate, a pattern defect in which a circuit pattern printed on the FPCB is arbitrarily detached should not occur. When the conductive connector is bonded to the FPCB, a bonding failure caused by the FPCB being bent should be minimized.

### DISCLOSURE

### Technical Problem

It is an objective of the present disclosure to provide a test socket capable of absorbing an impact upon contact with a semiconductor device and facilitating conduction between the semiconductor device and a test device even with a low pressure, and a method of manufacturing the test socket.

### Technical Solution

A method of manufacturing a test socket includes preparing a printed circuit board (PCB) on which a bonding pad is disposed, bonding a conductive wire on the bonding pad, mounting, on an upper surface of the PCB, a space through which the bonding pad is exposed, mounting, on an upper surface of the space, a base through which the bonding pad is exposed, mounting, on an upper surface of the base, a jig which covers the bonding pad, and injecting a liquid silicone rubber into a jig assembly by using the jig assembly as a mold, the jig assembly including the PCB, the space, the base, and the jig.

### Advantageous Effects

A wire and silicone can be easily assembled on a printed circuit board (PCB) even without using a separate mold, and because the wire is firmly bonded and misalignment of the bonded wire can be prevented, reliability of an assembly process can be increased.

### DESCRIPTION OF DRAWINGS

FIGS. 1A and 1B are respectively a top perspective view and a cross-sectional perspective view illustrating a configuration of a test socket according to the present disclosure.

FIGS. 2A and 2B are respectively a top perspective view and a bottom perspective view illustrating a wire bonding process according to the present disclosure.

FIGS. 3A to 3C are respectively an exploded perspective view, a top perspective view, and a cross-sectional perspective view illustrating a jig assembly process according to the present disclosure.

FIGS. 4A and 4B are respectively a top perspective view and a cross-sectional perspective view illustrating a silicone injection process according to the present disclosure.

FIGS. 5A and 5B are respectively a top perspective view and a cross-sectional perspective view illustrating a jig removal process according to the present disclosure.

FIGS. 6A and 6B are respectively a top perspective view and a cross-sectional perspective view illustrating a space removal process according to the present disclosure.

FIGS. 7A to 7C are respectively an exploded perspective view, a top perspective view, and a cross-sectional perspective view illustrating a cone guide film attachment process according to the present disclosure.

FIG. 8 is an exploded perspective view illustrating a ball guide film attachment process according to the present disclosure.

FIG. 9 is a partially cut-away perspective view illustrating a configuration of a test socket according to an embodiment of the present disclosure.

FIG. 10 is a partially cut-away perspective view illustrating a configuration of a test socket according to another embodiment of the present disclosure.

FIG. 11 is a partially cut-away perspective view illustrating a configuration of a test socket according to still another embodiment of the present disclosure.

FIG. 12 is a perspective view illustrating a wire bonding process according to the present disclosure.

FIG. 13 is a perspective view illustrating a jig assembly process according to the present disclosure.

FIG. 14 is a perspective view illustrating a silicone injection process according to the present disclosure.

FIG. 15 is a perspective view illustrating a jig removal process according to the present disclosure.

FIG. 16 is a perspective view illustrating a space removal process according to the present disclosure.

FIG. 17 is a perspective view illustrating a cone guide film attachment process according to the present disclosure.

FIG. 18 is a perspective view illustrating a ball guide film attachment process according to the present disclosure.

FIG. 19 is a partially cut-away perspective view illustrating a configuration of a cone-type test socket according to an embodiment of the present disclosure.

FIG. 20 is a partially cut-away perspective view illustrating a configuration of a filler-type test socket according to another embodiment of the present disclosure.

FIG. 21 is a partially cut-away perspective view illustrating a configuration of a semi-spherical type test socket according to still another embodiment of the present disclosure.

FIG. 22 is a partially cut-away perspective view illustrating a configuration of a test socket in which a protective resin is coated on a silicone rubber according to an embodiment of the present disclosure.

FIG. 23 is a partially cut-away perspective view illustrating a configuration of a test socket in which a protective pad is mounted on a silicone rubber according to another embodiment of the present disclosure.

FIG. 24 is a partially cut-away perspective view illustrating a configuration of a test socket in which a protective spring is inserted into a silicone rubber according to still another embodiment of the present disclosure.

FIG. 25 is a partially cut-away perspective view illustrating a configuration of a test socket further including a contact guide film according to an embodiment of the present disclosure.

FIG. 26 is a partially cut-away perspective view illustrating a wire bonding process of the test socket according to the present disclosure.

FIG. 27 is a partially cut-away perspective view illustrating a jig assembly process of the test socket according to the present disclosure.

FIG. 28 is a partially cut-away perspective view illustrating a silicone injection process of the test socket according to the present disclosure.

FIG. 29 is a partially cut-away perspective view illustrating a configuration of a test socket including a cone type separate conductive silicone rubber according to an embodiment of the present disclosure.

FIG. 30 is a partially cut-away perspective view illustrating a configuration of a test socket including an arch type separate conductive silicone rubber according to another embodiment of the present disclosure.

FIG. 31 is a cross-sectional view illustrating a configuration of a test socket in which a pressing conductive silicone rubber is included in a contact guide film according to still another embodiment of the present disclosure.

FIG. 32 is a partially cut-away perspective view of a test socket including a separate printed circuit board (PCB) land according to the present disclosure.

FIG. 33 is a partially cut-away perspective view of a test socket further including a ball guide film on a PCB according to the present disclosure.

FIGS. 34 to 37 are partially cut-away perspective views of a test socket illustrating various embodiments of a PCB land according to the present disclosure.

FIG. 38 is a top perspective view illustrating a configuration of the test socket according to the present disclosure.

FIG. 39 is a top perspective view illustrating a configuration of a linear type multiple-wire complex according to the present disclosure.

FIG. 40 is a top perspective view illustrating a configuration of a twist type multiple-wire complex according to the present disclosure.

FIG. 41 is a top perspective view illustrating a configuration of a multiple-wire complex in which a solder-side conductive connector has a crown form according to the present disclosure.

FIG. 42 is a bottom perspective view illustrating a configuration of a multiple-wire complex in which a pad-side conductive connector has a crown form according to the present disclosure.

FIG. 43 is a partially cut-away perspective view illustrating a configuration of a test socket including a conductive wire bonding structure using a conductive ball according to the present disclosure.

FIG. 44 is a schematic cross-sectional view illustrating a configuration in which a conductive ball is integrated with a conductive wire and a coil spring by reflow.

FIG. 45 is a partially cut-away perspective view illustrating a wire bonding process in a method of manufacturing a test socket according to the present disclosure.

FIG. 46 is a partially cut-away perspective view illustrating a coil spring insertion process in the method of manufacturing the test socket according to the present disclosure.

FIG. 47 is a partially cut-away perspective view illustrating a conductive ball mounting process in the method of manufacturing the test socket according to the present disclosure.

FIG. 48 is a partially cut-away perspective view illustrating a conductive ball reflow process in the method of manufacturing the test socket according to the present disclosure.

FIG. 49 is a partially cut-away perspective view illustrating a jig assembly assembling process in the method of manufacturing the test socket according to the present disclosure.

FIG. 50 is a partially cut-away perspective view illustrating a silicone injection process in the method of manufacturing the test socket according to the present disclosure.

FIG. 51 is a partially cut-away perspective view illustrating a jig assembly removal process in the method of manufacturing the test socket according to the present disclosure.

FIGS. 52A and 52B are respectively a perspective view and a cross-sectional view illustrating a configuration of a test socket according to the present disclosure.

FIGS. 53A and 53B are respectively a perspective view and a cross-sectional view illustrating a process of preparing a bonding-side substrate according to the present disclosure.

FIGS. 54A and 54B are respectively a perspective view and a cross-sectional view illustrating a process of bonding a conductive wire on a bonding flexible PCB (FPCB) film according to the present disclosure.

FIGS. 55A and 55B are respectively a perspective view and a cross-sectional view illustrating a process of preparing a solder-side substrate on the bonding-side substrate according to the present disclosure.

FIGS. 56A and 56B are respectively a perspective view and a cross-sectional view illustrating a process of assembling the bonding-side substrate and the solder-side substrate according to the present disclosure.

FIGS. 57A and 57B are respectively a perspective view and a cross-sectional view illustrating a process of soldering a conductive wire on a solder FPCB film according to the present disclosure.

FIGS. 58A and 58B are respectively a perspective view and a cross-sectional view illustrating a silicone injection process according to the present disclosure.

### MODES OF THE INVENTION

Advantages and features of the present disclosure and a method of achieving the same should become clear with embodiments described in detail below with reference to the accompanying drawings. However, the present disclosure is not limited to embodiments disclosed below and is realized in various other forms. The present embodiments make the disclosure of the present disclosure complete and are provided to completely inform one of ordinary skill in the art to which the present disclosure pertains of the scope of the invention. The present disclosure is defined only by the scope of the claims. In the drawings, the sizes and relative sizes of layers and regions may be exaggerated for clarity. Like reference numerals refer to like elements throughout.

Embodiments disclosed herein will be described with reference to ideal schematic plan views and cross-sectional views of the present disclosure. Accordingly, shapes of the exemplary views may be modified depending on manufacturing techniques and/or allowable errors. Therefore, the embodiments of the present disclosure are not limited to the specific shapes illustrated in the exemplary views, but may include changes in shapes generated according to manufacturing processes. Therefore, regions illustrated in the drawings have schematic characteristics. In addition, the shapes of the regions shown in the drawings exemplify specific shapes of regions in a test socket and do not limit the scope of the disclosure.

Hereinafter, a preferable first embodiment of a test socket according to the present disclosure having the above-described configuration will be described in detail with reference to the accompanying drawings.

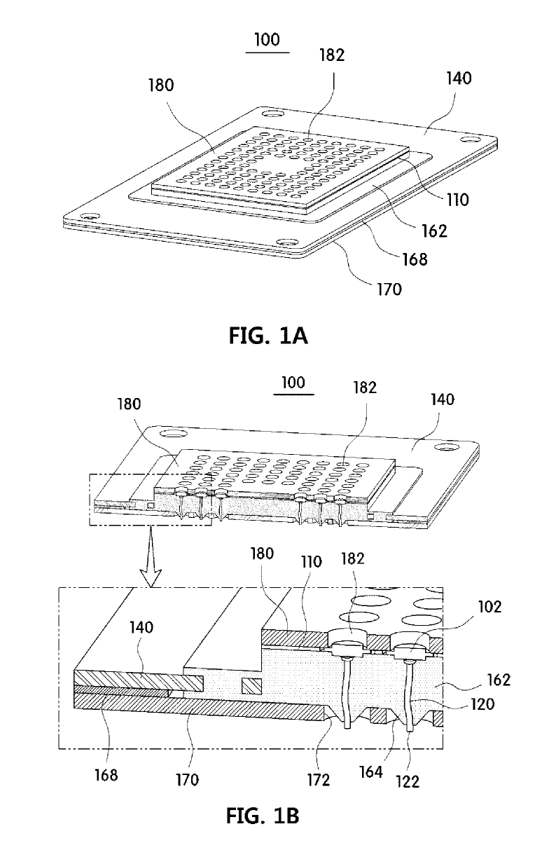

Referring to FIGS. 1A and 1B, a test socket 100 of the present disclosure includes a printed circuit board (PCB) 110 at which a bonding pad 102 is formed, a conductive wire 120 wire-bonded on the bonding pad 102 and extending vertically therefrom, an insulating silicone rubber 162 configured to elastically support the conductive wire 120 at one surface of the PCB 110, and a base 140 supported to partially overlap an edge of the insulating silicone rubber 162.

A cone supporter 164 coming in contact with a terminal of a test device is further included at one surface of the insulating silicone rubber 162. To reinforce a contact characteristic between the conductive wire 120 and the terminal of the test device, the cone supporter 164 performs a function of elastically supporting the conductive wire 120 inserted thereinto from the side. Although the cone supporter 164 is formed in a cone shape having a flat end in the drawings, embodiments are not necessarily limited thereto, and cases in which the cone supporter 164 is formed in a dome shape, an arch shape, or the like is not excluded.

The conductive wire 120 passes through the insulating silicone rubber 162, passes through the cone supporter 164, and protrudes and extends from an upper surface of the insulating silicone rubber 162. The conductive wire 120 forms a conductive connector 122 at the protruding and extending portion thereof.

Consequently, one end of the conductive wire 120 is connected to the bonding pad 102 through a bonding joining portion 104, and the other end thereof is exposed to the outside through the conductive connector 122.

Here, the bonding pad 102 is a portion coming in contact with a ball of a semiconductor device to be tested, and the conductive connector 122 is a portion coming in contact with a terminal of a test device which tests the semiconductor device to be tested.

A rigid PCB in which a circuit is configured by printing copper (Cu) on an epoxy resin or phenol resin or a flexible PCB (FPCB) in which various circuit patterns are formed on a polyimide (PI) film having high flexibility by using Cu, gold (Au), or other conductive materials may be used as the PCB 110.

The conductive wire 120 may be plated with Au or nickel (Ni), which is conductive. While testing a semiconductor device, even when the test socket 100 is pressed by the semiconductor device, for an impact thereof to be absorbed while an electrical connection is maintained, the conductive wire 120 is not necessarily manufactured in a linear shape. For example, the conductive wire 120 may be formed in a zigzag shape or a helical spring shape, thereby absorbing a physical impact and minimizing damage.

The insulating silicone rubber 162 is not limited to a silicone rubber and may be any material having a predetermined elasticity. Examples of the insulating silicone rubber 162 may include a heat-resistant polymer material having a crosslinking structure, such as a polybutadiene rubber, a urethane rubber, a natural rubber, a polyisoprene rubber, and other elastic rubbers.

The insulating silicone rubber 162 is formed in a rectangular shape having an extremely wide area in comparison to a thickness thereof, and the base 140 is a quadrangular frame which surrounds edges of the rectangular insulating silicone rubber 162. The base 140 is formed in the shape of a quadrangular frame, and a portion thereof at an inner side of a window is inserted into the insulating silicone rubber 162.

The present disclosure may further include a cone guide film 170 configured to guide the terminal of the test device so that the terminal of the test device is not mismatched with the conductive connector 122 of the conductive wire 120. At the cone guide film 170, a connector hole 172 in which the cone supporter 164 is disposed, and through which the conductive connector 122 passes is formed in one-to-one correspondence with the conductive connector 122. As a result, the cone guide film 170 prevents the terminal from being arbitrarily detached after the terminal comes into contact with the conductive connector 122.

The present disclosure may further include a ball guide film 180 configured to guide the ball of the semiconductor device so that the ball of the semiconductor device is not mismatched with the bonding pad 102. At the ball guide film 180, a pad hole 182 in which the bonding pad 102 is disposed and the ball is seated is formed in one-to-one correspondence with the bonding pad 102. As a result, the ball guide film 180 prevents the ball from being arbitrarily detached after the ball comes into contact with the bonding pad 102.

The cone guide film 170 and the ball guide film 180 may be composed of a PI film having a small thickness and excellent wear resistance. However, embodiments are not necessarily limited thereto, and the cone guide film 170 and the ball guide film 180 may be manufactured with any plastic film such as a polyphenylene sulfide (PPS) film, a polyetheretherketone (PEEK) film, a polyphthalamide (PPA) film, a polysulfone (PSU) film, a polyethersulfone (PES) film, a polyetherimide (PEI) film, and a polyethylene-2,6-naphthalenedicarboxylate (PEN) film.

Hereinafter, a method of manufacturing a test socket according to the present disclosure will be described with reference to the drawings.

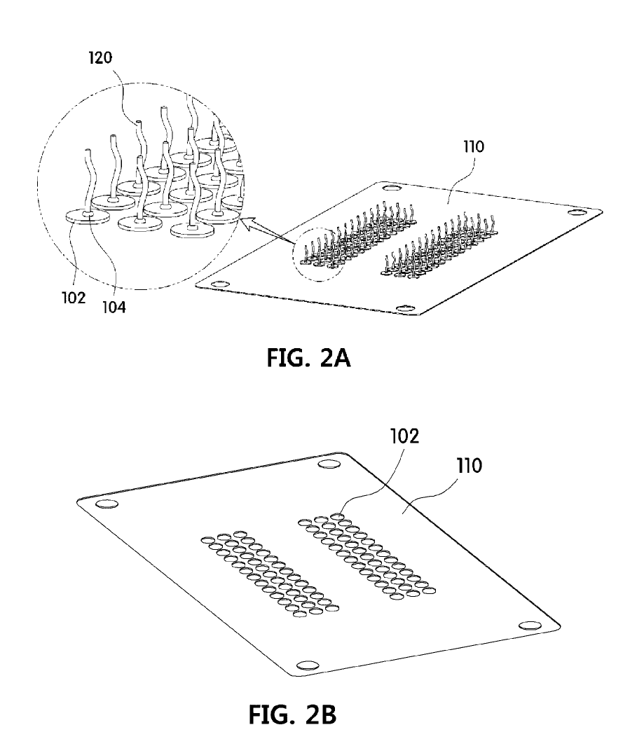

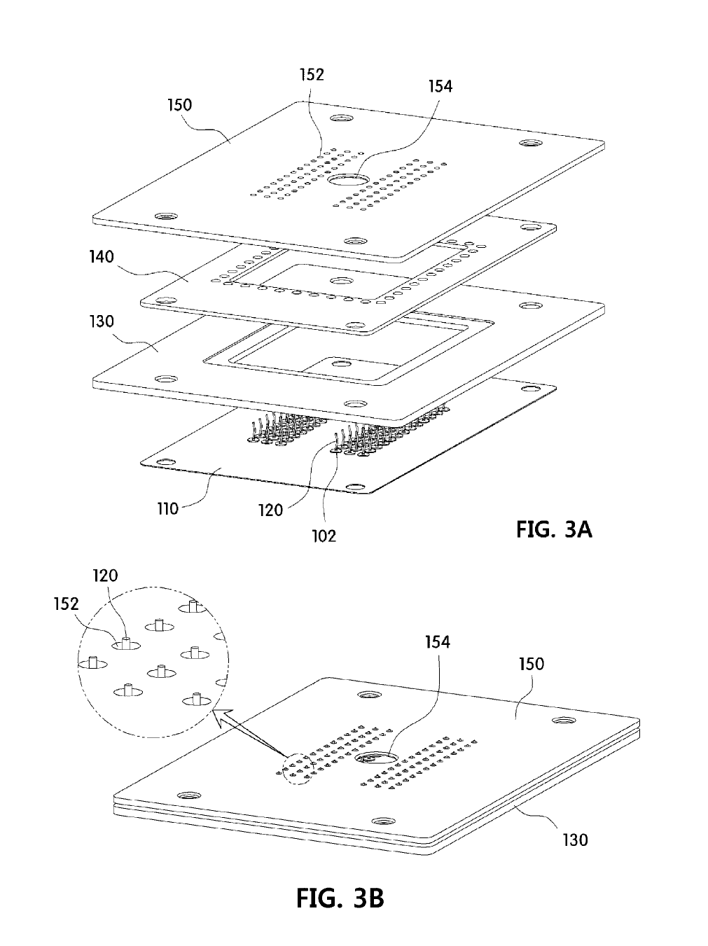

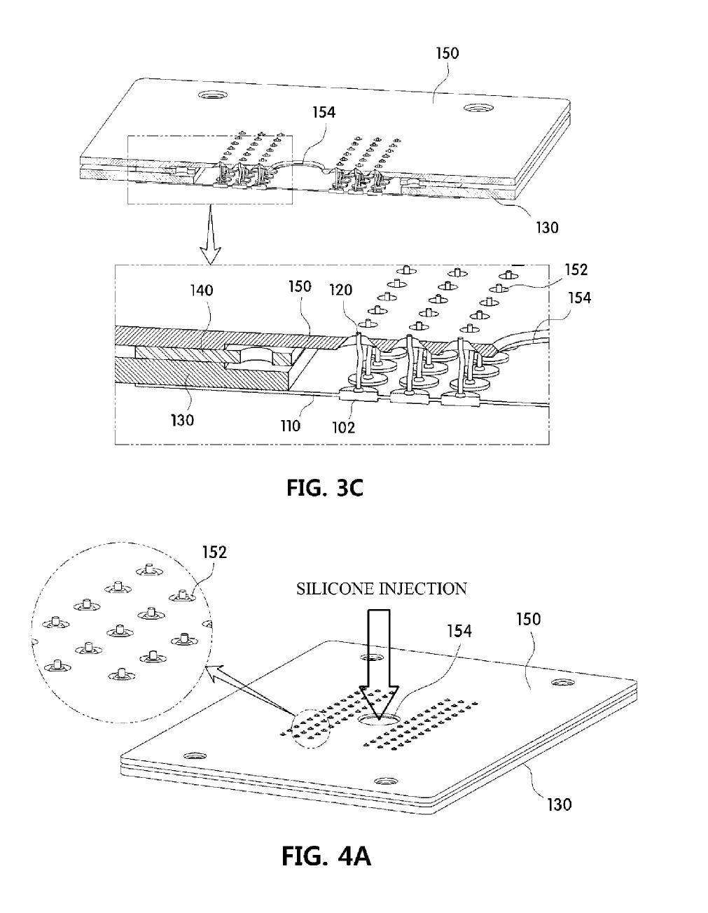

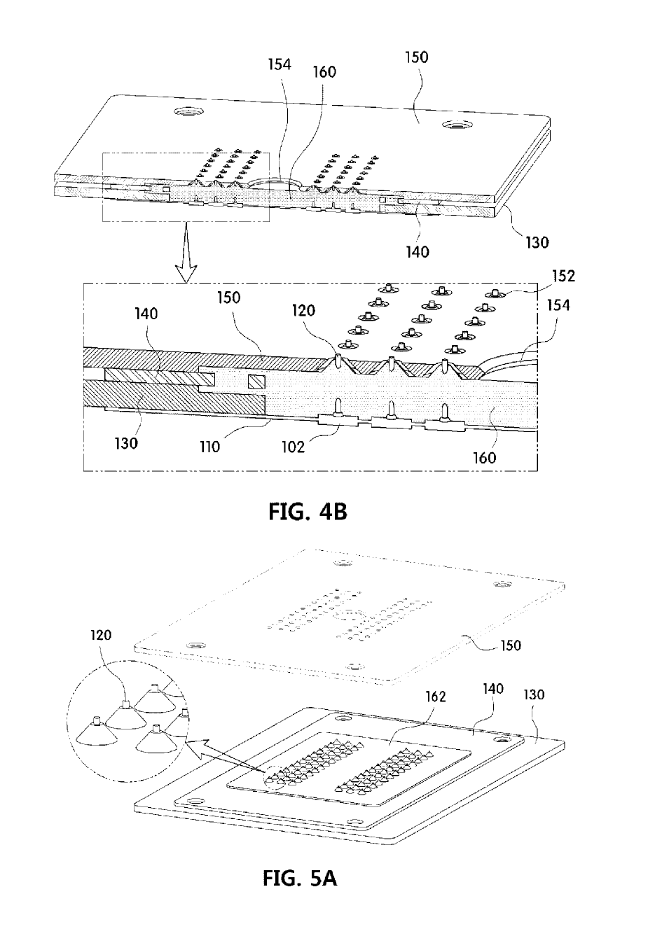

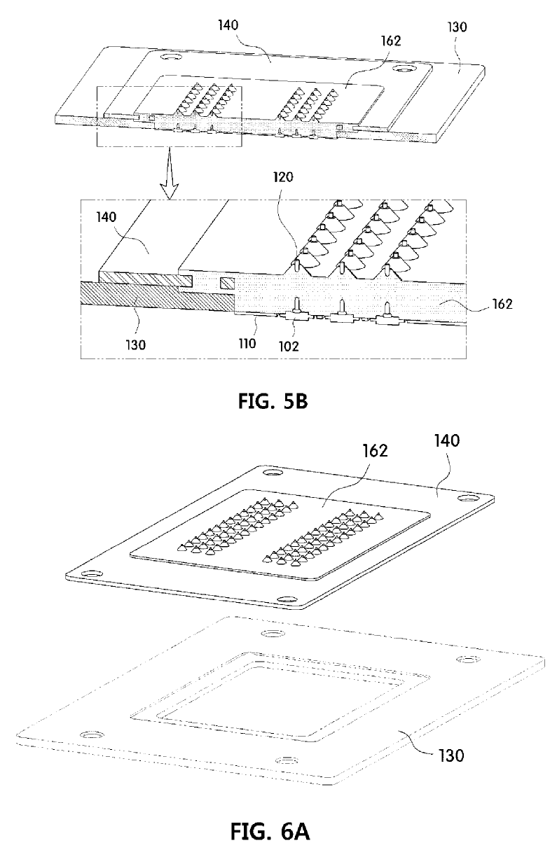

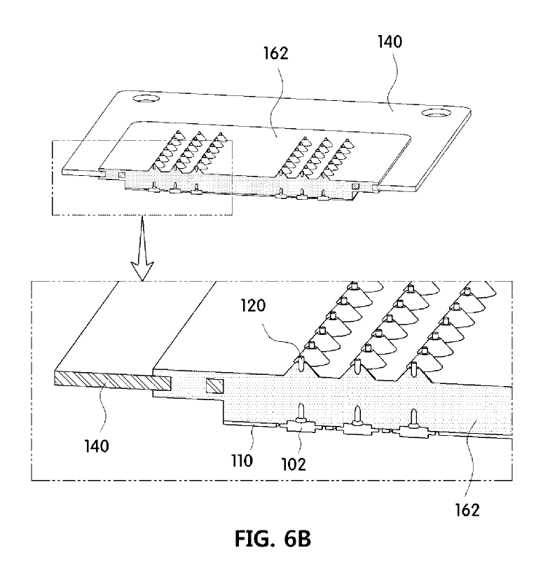

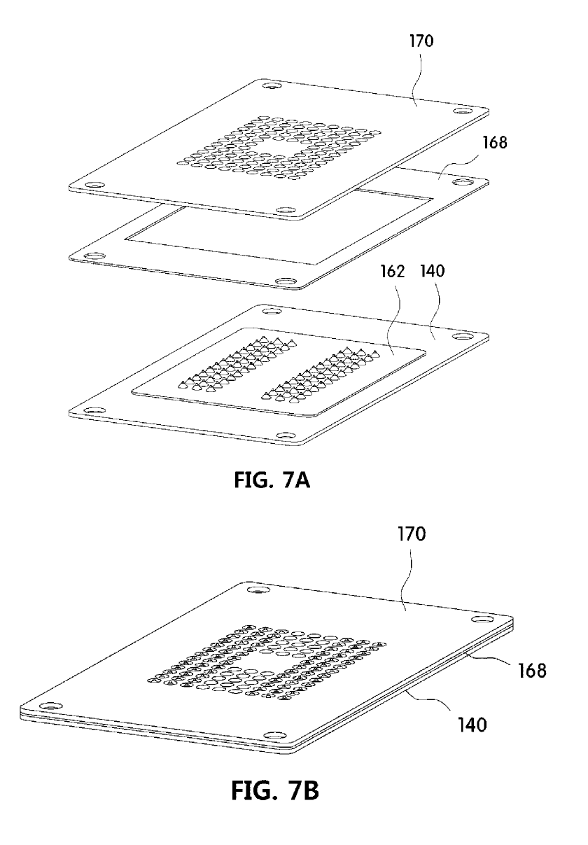

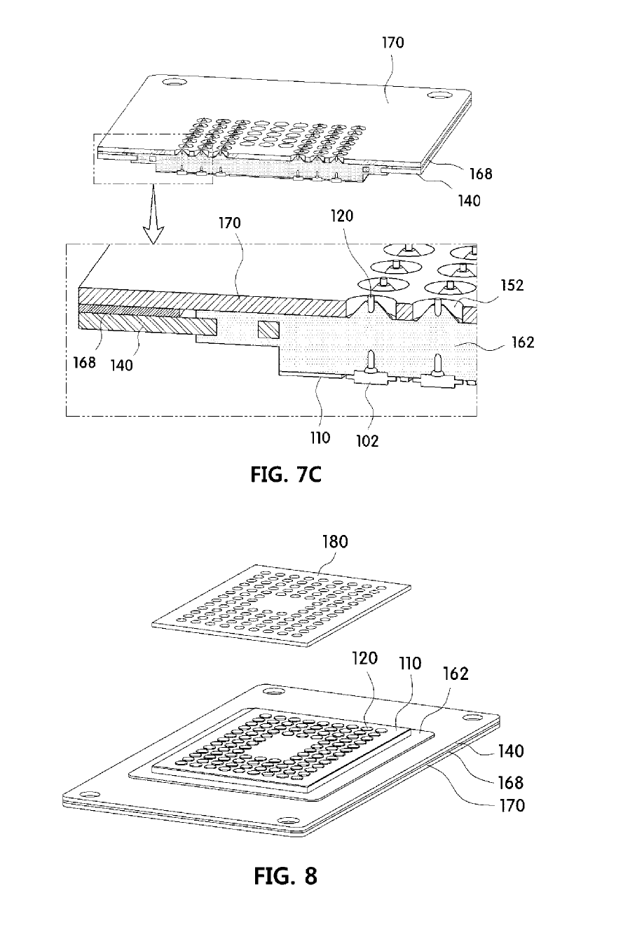

The method of manufacturing the test socket according to the present disclosure is illustrated in FIGS. 2A to 8. A wire bonding process is illustrated in FIGS. 2A and 2B, a jig assembly process is illustrated in FIGS. 3A to 3C, a silicone injection process is illustrated in FIGS. 4A and 4B, a jig removal process is illustrated in FIGS. 5A and 5B, a space removal process is illustrated in FIGS. 6A and 6B, a cone guide film attachment process is illustrated in FIGS. 7A to 7C, and a ball guide film attachment process is illustrated in FIG. 8.

Referring to FIGS. 2A and 2B, the PCB 110 is prepared.

The bonding pad 102 is formed on the PCB 110. The bonding pad 102 may be manufactured by electroplating or electrolessly plating Cu.

The conductive wire 120 is bonded on the PCB 110. The conductive wire 120 comes into contact with the bonding pad 102. In this way, the bonding joining portion 104 may be formed.

The conductive wire 120 may be formed of a single wire or multiple wires. The conductive wire 120 may provide elasticity to a device coming into contact therewith through a shape change. For example, during a wire bonding process, the shape of the conductive wire 120 may be changed in various ways by horizontally moving the conductive wire 120 at a predetermined angle while joining the conductive wire 120 to the bonding pad 102.

According to an embodiment of the present disclosure, after the wire bonding process, the conductive wire 120 may be primarily plated with Ni. Ni may have somewhat low conductivity, and in a case of a high-frequency wave, a signal may flow to a surface of Ni, and a characteristic thereof may be deteriorated. Thus, Au may be secondarily plated on Ni.

A FPCB is used as the PCB 110. It is easy to design a circuit pattern using a screen printing or photolithography process and workability is high when the FPCB is used. Particularly, the FPCB is the most suitable for a continuous roll-to-roll process. For example, when a flexible circuit film in which a circuit pattern is printed at one surface or both surfaces is used as the PCB 110, a continuous process is possible.

Referring to FIGS. 3A, 3B, and 3C, a jig assembly is assembled.

First, a space 130 having edges through which the PCB 110 is exposed is mounted at an upper surface of the PCB 110. Then, the base 140 through which the PCB 110 is exposed is mounted on the space 130. Lastly, a jig 150 configured to cover the PCB 110 is installed on the base 140. Align holes (no reference numerals) configured to vertically align the jig assembly may be formed at corners of each of the space 130, the base 140, and the jig 150. A plurality of cone holes 152 are formed with a predetermined rule at the jig 150.

In this way, the jig assembly is used as a mold for injecting a liquid silicone rubber 160 which will be described below. In a broad sense, in addition to the PCB 110 disposed at the bottom, the jig assembly includes the space 130 mounted at the upper surface of the PCB 110, the base 140 mounted at an upper surface of the space 130, and the jig 150 mounted on the base 140. Here, the space 130 and the base 140 are quadrangular frames each having a window, and the bonding pad 102 is exposed through the window. Conversely, the jig 150 covers the bonding pad 102.

The jig 150 includes, at a center thereof, a silicone injection hole 154 through which silicone is injected, which will be described below. After the test socket manufacturing process is completed, the space 130 and the jig 150, except for the base 140, are removed from the jig assembly.

Referring to FIGS. 4A and 4B, a liquid silicone rubber is injected into the jig assembly.

In the jig assembly of the present disclosure, the PCB 110 is disposed at the bottom, and the jig 150 including the silicone injection hole 154 is disposed at the uppermost portion so that the liquid silicone rubber 160 is injected through the jig 150. The silicone injection hole 154 is installed at the jig 150 because the plurality of cone holes 152 are formed at the jig 150.

One should be careful not to deform the conductive wire 120 while the liquid silicone rubber 160 is being injected. A silicone injection pressure should be adjusted according to a hardness of silicone and a material or thickness of the conductive wire 120. Particularly, because the plurality of cone holes 152 are formed at the upper surface of the jig 150, silicone may overflow when one fails to adjust a pressure of injecting the liquid silicone rubber 160.

Referring to FIGS. 5A and 5B, the jig at the top is removed.

When the jig 150 is removed, the liquid silicone rubber 160 may not be sufficiently hardened as much as the insulating silicone rubber 162. Here, an additional hardening process may be further performed.

Referring to FIGS. 6A and 6B, the space is removed.

When the space 130 is removed, a portion of the PCB 110 horizontally extending to the space 130 may be removed together by laser cutting. The base 140 is kept without change to support the PCB 110 which is prone to distortion.

Referring to FIGS. 7A, 7B, and 7C, the cone guide film is attached.

The cone guide film 170 configured to protect the insulating silicone rubber 162 and facilitate contact between the terminal of the test device and the conductive wire 120 is attached to an upper surface of the insulating silicone rubber 162 from which the jig 150 is removed. The reference numeral 168 indicates a dummy.

Referring to FIG. 8, the ball guide film is attached.

The PCB 110 is flipped, and the ball guide film 180 configured to guide the ball of the semiconductor device to facilitate contact between the ball of the semiconductor device and the bonding pad 102 is attached to a bottom surface of the PCB 110.

Hereinafter, a preferable second embodiment of a test socket according to the present disclosure having the above-described configuration will be described in detail with reference to the accompanying drawings.

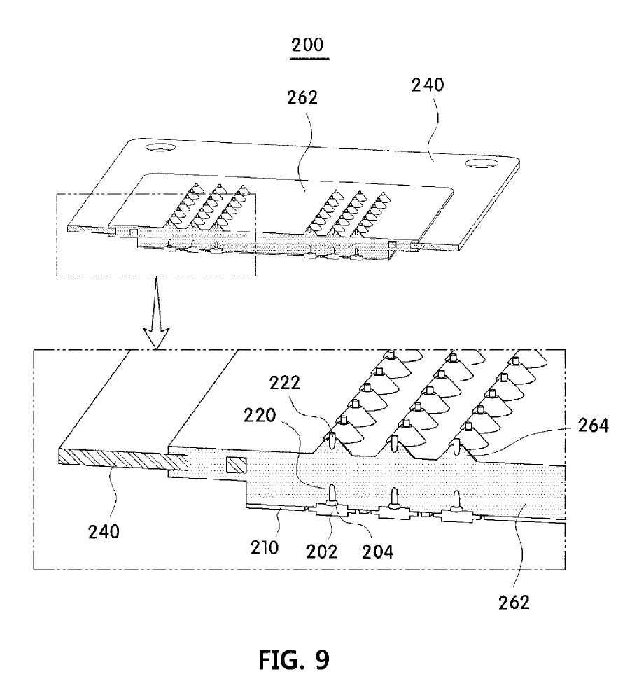

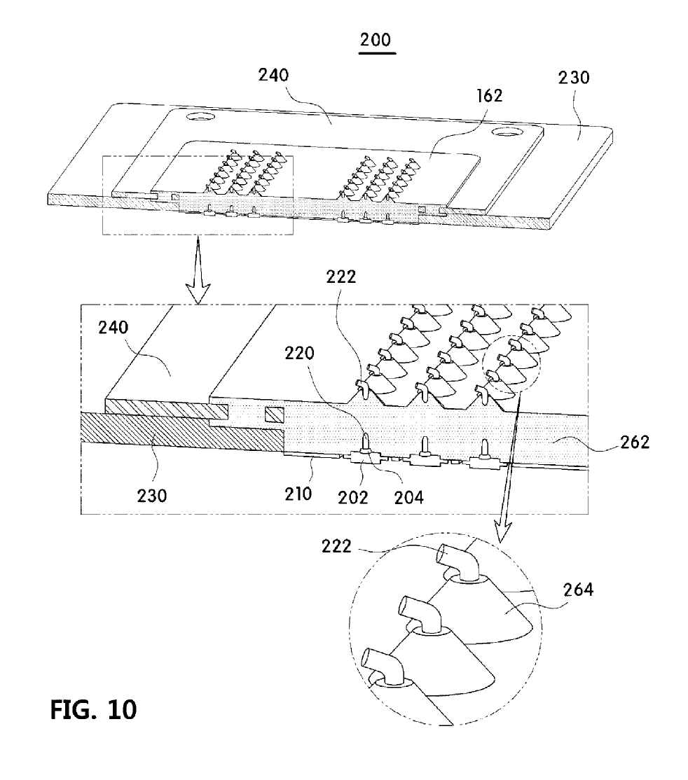

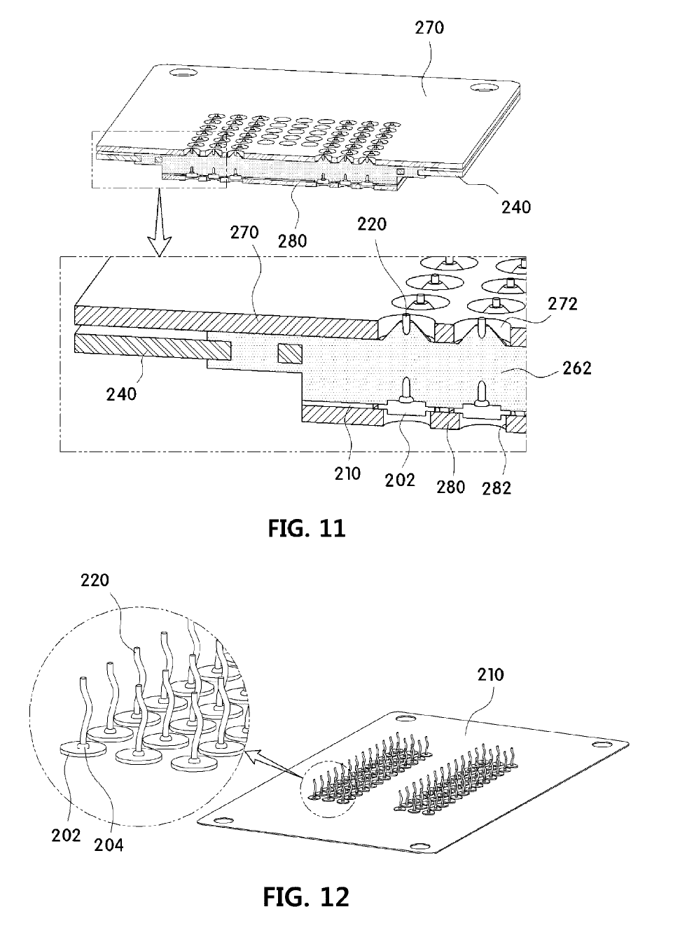

A partially cut-away perspective view of a configuration of a test socket according to the present disclosure is illustrated in FIG. 9, a configuration of a test socket in which a conductive wire is deformed according to another embodiment of the present disclosure is illustrated in FIG. 10, and a configuration of a test socket further including a guide film according to still another embodiment of the present disclosure is illustrated in FIG. 11.

Referring to FIG. 9, a test socket 200 of the present disclosure includes a PCB 210 at which a bonding pad 202 is formed, a conductive wire 220 wire-bonded on the bonding pad 202 and extending vertically therefrom, an insulating silicone rubber 262 configured to elastically support the conductive wire 220 at one surface of the PCB 210, and a base 240 supported to partially overlap an edge of the insulating silicone rubber 262.

A cone supporter 264 coming in contact with a terminal of a test device is further included at one surface of the insulating silicone rubber 262. To reinforce a contact characteristic between the conductive wire 220 and the terminal of the test device, the cone supporter 264 performs a function of elastically supporting the conductive wire 120 inserted thereinto from the side. Although the cone supporter 264 is formed in a cone shape having a sharp or flat end in the drawings, embodiments are not necessarily limited thereto, and cases in which the cone supporter 264 is formed in a dome shape, an arch shape, or the like is not excluded.

The conductive wire 220 passes through the insulating silicone rubber 262, passes through the cone supporter 264, and protrudes and extends from an upper surface of the insulating silicone rubber 262. The conductive wire 220 forms a conductive connector 222 at the protruding and extending portion thereof.

Consequently, one end of the conductive wire 220 is connected to the bonding pad 202 through a bonding joining portion 204, and the other end thereof is exposed to the outside through the conductive connector 222.

Here, the bonding pad 202 is a portion coming in contact with a ball of a semiconductor device to be tested, and the conductive connector 222 is a portion coming in contact with a terminal of a test device which tests the semiconductor device to be tested.

A rigid PCB in which a circuit is configured by printing Cu on an epoxy resin or phenol resin or a FPCB in which various circuit patterns are formed on a PI film having high flexibility by using Cu, Au, or other conductive materials may be used as the PCB 210.

The conductive wire 220 may be plated with Au or nickel (Ni), which is conductive. While testing a semiconductor device, even when the test socket 200 is pressed by the semiconductor device, for an impact thereof to be absorbed while an electrical connection is maintained, the conductive wire 220 is not necessarily manufactured in a linear shape. For example, the conductive wire 220 may be formed in a zigzag shape or a helical spring shape, thereby absorbing a physical impact and minimizing damage.

The insulating silicone rubber 262 is not limited to a silicone rubber and may be any material having a predetermined elasticity. Examples of the insulating silicone rubber 262 may include a heat-resistant polymer material having a crosslinking structure, such as a polybutadiene rubber, a urethane rubber, a natural rubber, a polyisoprene rubber, and other elastic rubbers.

The insulating silicone rubber 262 is formed in a rectangular shape having an extremely wide area in comparison to a thickness thereof, and the base 240 is a quadrangular frame which surrounds edges of the rectangular insulating silicone rubber 262. The base 240 is formed in the shape of a quadrangular frame, and a portion thereof at an inner side of a window is inserted into the insulating silicone rubber 262.

Referring to FIG. 10, according to another embodiment of the present disclosure, the conductive connector 222 may be tilted at a predetermined angle from a direction perpendicular to the conductive wire 220 and come into edge contact with the terminal of the test device. For example, the conductive connector 222 is tilted in a diagonal or curved shape and provides an elastic force upon contact with the terminal of the test device.

Also, the conductive connector 222 improves a contact characteristic. Although an external terminal such as a conductive ball or a bump is formed with a metal alloy having excellent electrical conductivity, a natural oxide film is applied on a surface of the external terminal during a forming process thereof. Such a natural oxide film is formed at a terminal contact surface such that the natural oxide film interferes with electrical conduction with the conductive connector 222 and degrades electrical performance. However, an edge portion of the conductive connector 222 comes into contact with the external terminal such that the natural oxide film is broken at a boundary therebetween, and an overall contact characteristic is reinforced.

In this way, an end of the conductive wire 220 may be bent as desired using the jig to be inclined or bent, and a height or shape of the bent conductive wire 220 may be adjusted according to the jig.

Referring to FIG. 11, the present disclosure may further include a cone guide film 270 configured to guide the terminal of the test device so that the terminal of the test device is not mismatched with the conductive connector 222 of the conductive wire 220. At the cone guide film 270, a connector hole 272 in which the cone supporter 264 is disposed and through which the conductive connector 222 passes is formed in one-to-one correspondence with the conductive connector 222. As a result, the cone guide film 270 prevents the terminal from being arbitrarily detached after the terminal comes into contact with the conductive connector 222.

The present disclosure may further include a ball guide film 280 configured to guide the ball of the semiconductor device so that the ball of the semiconductor device is not mismatched with the bonding pad 202. At the ball guide film 280, the a pad hole 282 in which bonding pad 202 is disposed and the ball is seated is formed in one-to-one correspondence with the bonding pad 202. As a result, the ball guide film 280 prevents the ball from being arbitrarily detached after the ball comes into contact with the bonding pad 202.

The cone guide film 270 and the ball guide film 280 may be composed of a PI film having a small thickness and excellent wear resistance. However, embodiments are not necessarily limited thereto, and the cone guide film 270 and the ball guide film 280 may be manufactured with any plastic film such as a PPS film, a PEEK film, a PPA film, a PSU film, a PES film, a PEI film, and a PEN film.

Hereinafter, a method of manufacturing a test socket according to the present disclosure will be described with reference to the drawings.

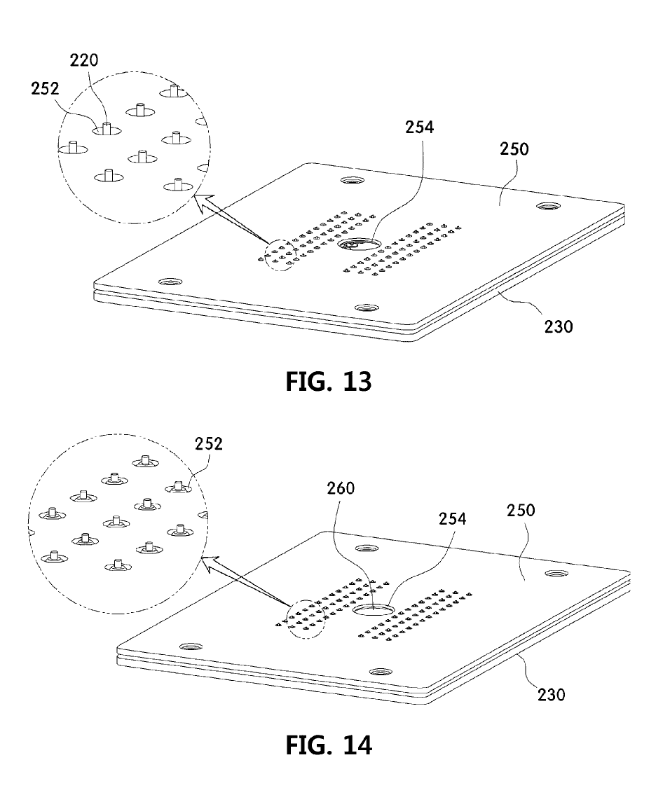

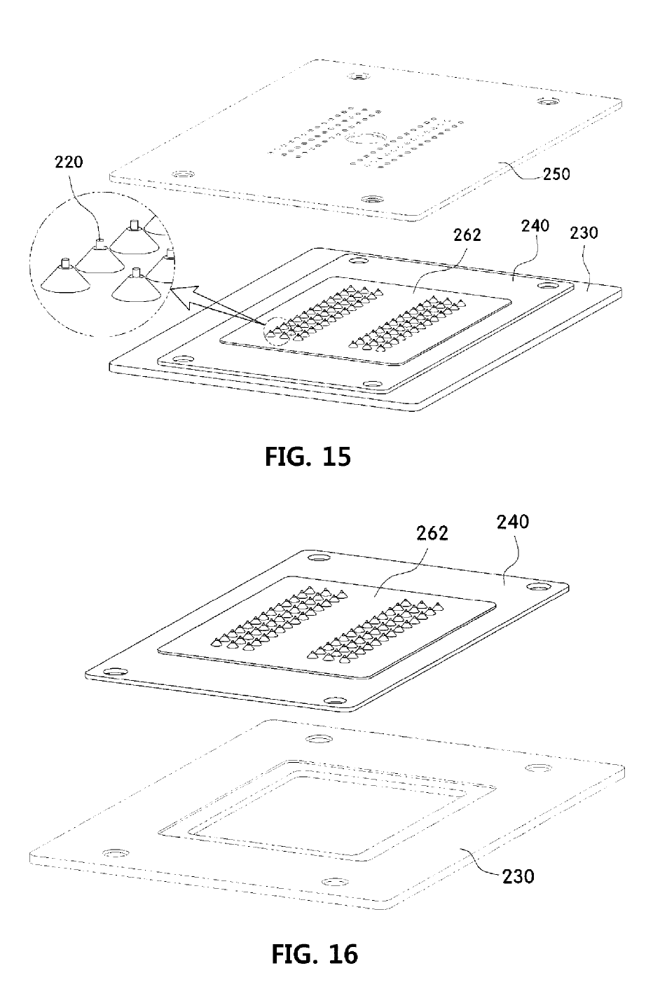

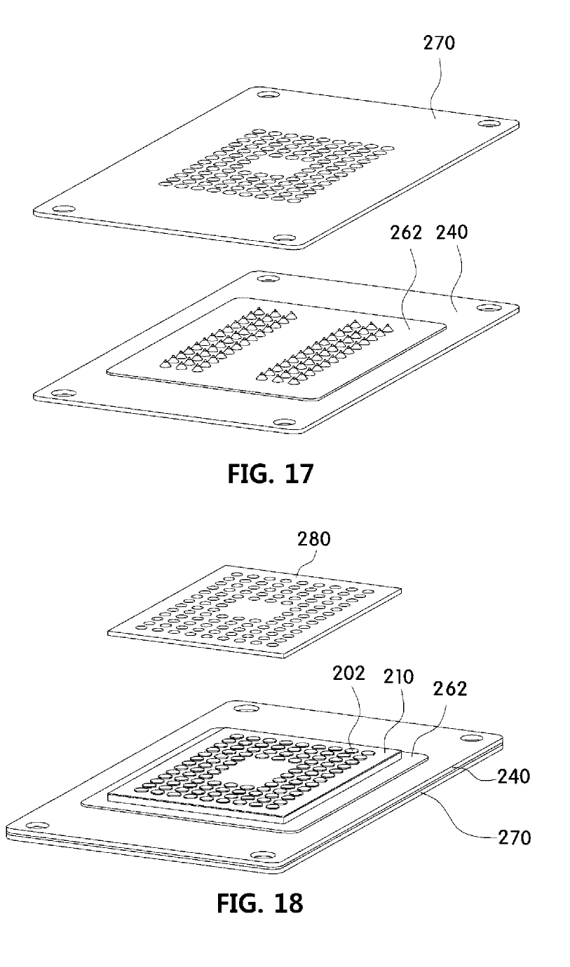

The method of manufacturing the test socket according to the present disclosure is illustrated in FIGS. 12 to 18. A wire bonding process is illustrated in FIG. 12, a jig assembly process is illustrated in FIG. 13, a silicone injection process is illustrated in FIG. 14, a jig removal process is illustrated in FIG. 15, a space removal process is illustrated in FIG. 16, a cone guide film attachment process is illustrated in FIG. 17, and a ball guide film attachment process is illustrated in FIG. 18.

Referring to FIG. 12, the PCB 210 is prepared. A plurality of bonding pads 202 are formed on the PCB 210. The bonding pads 202 may be manufactured by electroplating or electrolessly plating Cu. The conductive wire 220 is bonded on the PCB 210. The conductive wire 220 comes into contact with the bonding pad 202. In this way, the bonding joining portion 204 may be formed.

The conductive wire 220 may be formed of a single wire or multiple wires. The conductive wire 220 may provide elasticity to a device coming into contact therewith through a shape change. For example, during a wire bonding process, the shape of the conductive wire 220 may be changed in various ways by horizontally moving the conductive wire 220 at a predetermined angle while joining the conductive wire 220 to the bonding pads 202.

A FPCB is used as the PCB 210. It is easy to design a circuit pattern using a screen printing or photolithography process and workability is high when the FPCB is used. Particularly, the FPCB is the most suitable for a continuous roll-to-roll process. For example, when a flexible circuit film in which a circuit pattern is printed at one surface or both surfaces is used as the PCB 210, a continuous process is possible.

Referring to FIG. 13, a jig assembly is assembled. First, a space 230 having edges through which the PCB 210 is exposed is mounted at an upper surface of the PCB 210. Then, the base 240 (see FIG. 15) through which the PCB 210 is exposed is mounted on the space 230. Lastly, a jig 250 configured to cover the PCB 210 is installed on the base 240. Align holes (no reference numerals) configured to vertically align the jig assembly may be formed at corners of each of the space 230, the base 240, and the jig 250. A plurality of cone holes 252 are formed with a predetermined rule at the jig 250.

In this way, the jig assembly is used as a mold for injecting a liquid silicone rubber 260 which will be described below. In a broad sense, in addition to the PCB 210 disposed at the bottom, the jig assembly includes the space 230 mounted at the upper surface of the PCB 210, the base 240 mounted at an upper surface of the space 230, and the jig 250 mounted on the base 240. Here, although not illustrated in the drawings, the space 230 and the base 240 are quadrangular frames each having a window, and the bonding pads 202 are exposed through the window. Conversely, the jig 250 covers the bonding pads 202. The jig 250 includes, at a center thereof, a silicone injection hole 254 through which siliconeis injected, which will be described below.

Referring to FIG. 14, a liquid silicone rubber is injected into the jig assembly. In the jig assembly of the present disclosure, the PCB 210 is disposed at the bottom, and the jig 250 including the silicone injection hole 254 is disposed at the uppermost portion so that the liquid silicone rubber 260 is injected through the jig 250. Here, one should be careful not to deform the conductive wire 120 while the liquid silicone rubber 260 is being injected. A silicone injection pressure should be adjusted according to a hardness of silicone and a material or thickness of the conductive wire 220. Particularly, because the plurality of cone holes 252 are formed at the upper surface of the jig 250, silicone may overflow when one fails to adjust a pressure of injecting the liquid silicone rubber 260.

Referring to FIG. 15, the jig at the top is removed. When the jig 250 is removed, the liquid silicone rubber 260 may not be sufficiently hardened as much as the insulating silicone rubber 262. Here, an additional hardening process may be further performed.

Referring to FIG. 16, the space is removed. When the space 230 is removed, a portion of the PCB 210 horizontally extending to the space 230 may be removed together by laser cutting. The base 240 is kept without change to maintain an overall form.

Referring to FIG. 17, the cone guide film is attached. The cone guide film 270 configured to protect the insulating silicone rubber 262 and facilitate contact between the terminal of the test device and the conductive wire 220 is attached to an upper surface of the insulating silicone rubber 262 from which the jig 250 is removed.

Referring to FIG. 18, the ball guide film is attached. The ball guide film 280 configured to guide the ball of the semiconductor device to facilitate contact between the ball of the semiconductor device and the bonding pads 202 is attached to a bottom surface of the PCB 210.

Hereinafter, a preferable third embodiment of a test socket according to the present disclosure having the above-described configuration will be described in detail with reference to the accompanying drawings.

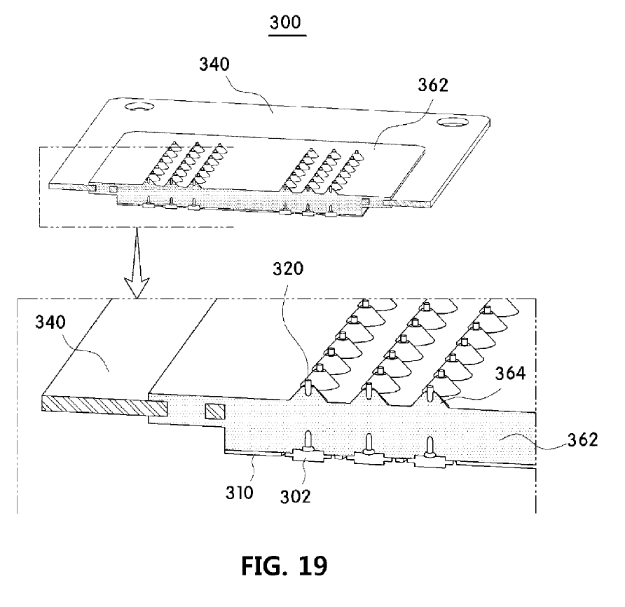

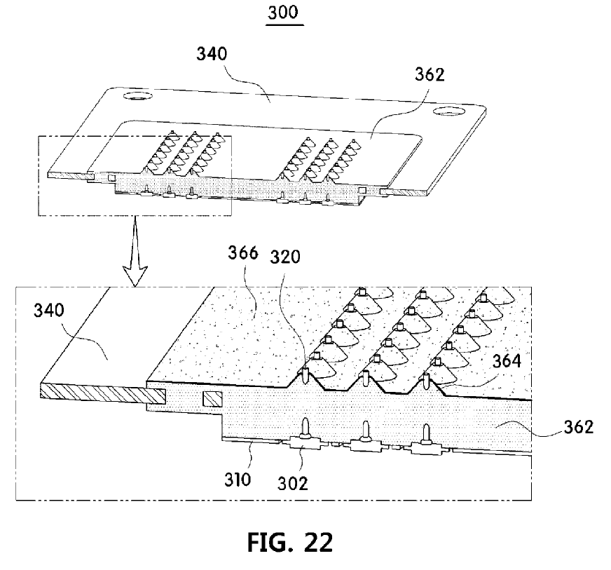

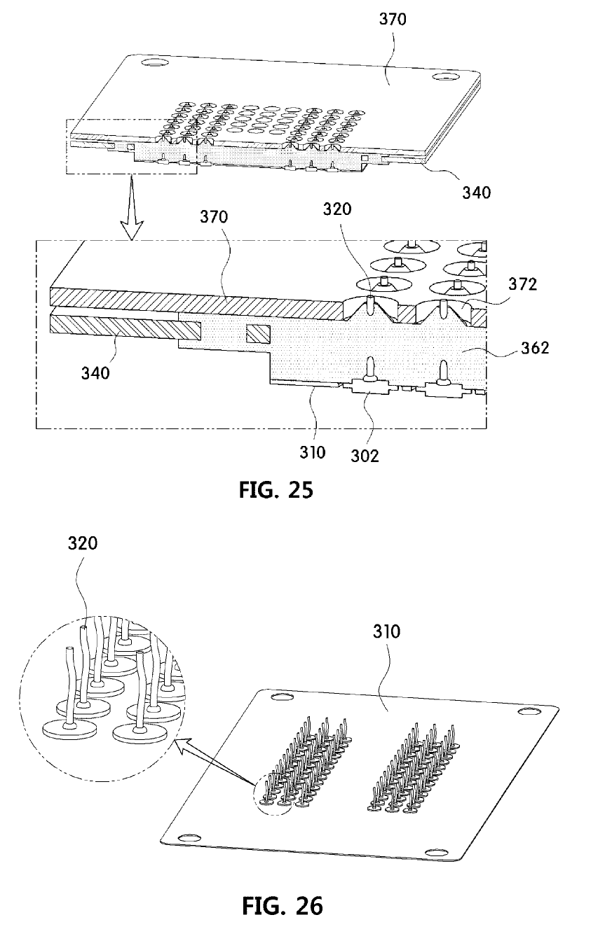

Partially cut-away perspective views of various shapes of a separate silicone rubber in a configuration of a test socket according to the present disclosure are introduced in FIGS. 19 to 21, complementary configurations for maintaining a shape of the separate silicone rubber according to the present disclosure are illustrated in FIGS. 22 to 24, and a configuration for preventing detachment of the separate silicone rubber after contact is illustrated in FIG. 25.

Referring to FIG. 19, a test socket 300 of the present disclosure includes a PCB 310, a plurality of conductive wires 320 connected using a bonding pad 302 on the PCB 310, a single insulating silicone rubber 362 disposed on the PCB 310, having the conductive wires 320 arranged at a constant interval in the horizontal direction and extending in a vertical direction, and a plurality of separate insulating silicone rubbers 364 integrally formed with the single insulating silicone rubber 362 and configured to independently support the conductive wires 320. The test socket 300 may further include a base 340 supported to partially overlap an edge of the insulating silicone rubber 362.

A rigid PCB in which a circuit is configured by printing Cu on an epoxy resin or phenol resin or a FPCB in which various circuit patterns are formed on a PI film having high flexibility by using Cu, Au, or other conductive materials may be used as the PCB 310.

The conductive wires 320 pass through the insulating silicone rubber 362, pass through the separate insulating silicone rubbers 364, and protrude and extend from upper surfaces thereof. In this way, the conductive wires 320 form electrical contact with a terminal of an external device at the protruding and extending portions thereof. One end of each of the conductive wires 320 is connected to the bonding pad 302 through a bonding joining portion, and the other end thereof is exposed to the outside.

The conductive wires 320 may be plated with Au or Ni, which is conductive. While testing a semiconductor device, even when the test socket 300 is pressed by the semiconductor device, for an impact thereof to be absorbed while an electrical connection is maintained, the conductive wires 320 are not necessarily manufactured in a linear shape. For example, the conductive wires 320 may be formed in a zigzag shape or a helical spring shape, thereby absorbing a physical impact and minimizing damage.

The single insulating silicone rubber 362 and the separate insulating silicone rubbers 364 are not limited to a silicone rubber and may be any material having a predetermined elasticity. Examples of the single insulating silicone rubber 362 and the separate insulating silicone rubbers 364 may include a heat-resistant polymer material having a crosslinking structure, such as a polybutadiene rubber, a urethane rubber, a natural rubber, a polyisoprene rubber, and other elastic rubbers. The single insulating silicone rubber 362 is formed in a rectangular shape having an extremely wide area in comparison to a thickness thereof, and the base 340 is a quadrangular frame which surrounds edges of the rectangular insulating silicone rubber 362.

In this way, the separate insulating silicone rubbers 364 coming into contact with the terminal of the test device are further included at one surface of the single insulating silicone rubber 362. To reinforce a contact characteristic between the conductive wires 320 and the terminal of the test device, the separate insulating silicone rubbers 364 may perform a function of elastically supporting the conductive wires 320 inserted thereinto from the side.

For example, for more accurate contact with the test device upon contact with the test device, the separate insulating silicone rubbers 364 may protrude in a corn shape or a trapezoidal shape whose diameter gradually decreases from the single insulating silicone rubber 362.

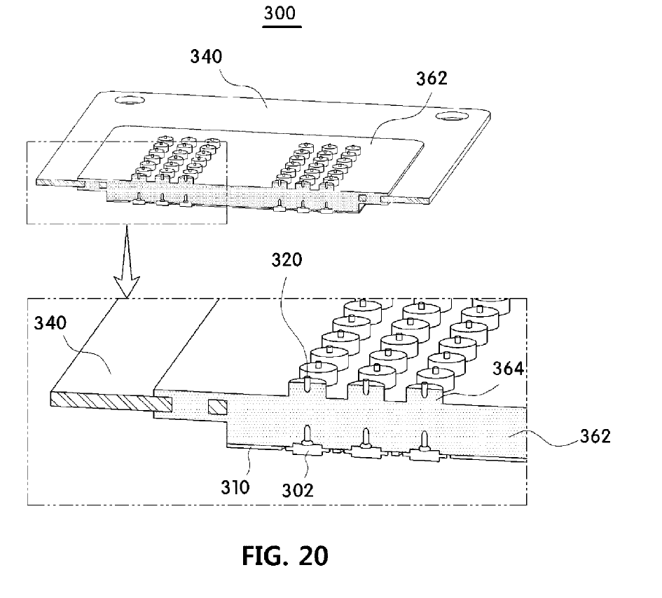

However, although the separate insulating silicone rubbers 364 are formed in a cone shape having a sharp or flat end in the present disclosure, embodiments are not necessarily limited thereto, and cases in which the separate insulating silicone rubbers 364 are formed in a dome shape, an arch shape, or the like may also be considered. Also, as illustrated in FIG. 20, to ensure independence of the separate insulating silicone rubbers 364, a shape change may be limited to only a simple pillar shape.

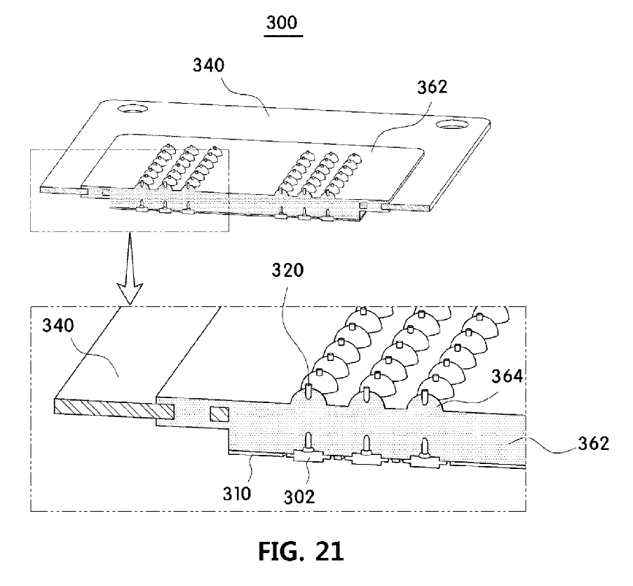

Referring to FIG. 21, the separate insulating silicone rubbers 364 of the present disclosure may protrude in an arch shape or a hemispherical form from an upper surface of the single insulating silicone rubber 362.

Referring to FIG. 22, surfaces of the separate insulating silicone rubbers 364 of the present disclosure may be entirely coated with a protective resin 366. The protective resin 366 may be formed of a type of a synthetic resin to maintain the shapes of the separate insulating silicone rubbers 364. Examples of the synthetic resin may include epoxy resin and other thermosetting resins and polyolefin resin and other thermoplastic resins. In addition, the synthetic resin may include a vinyl resin.

For example, the protective resin 366 may be applied on the surfaces of the separate insulating silicone rubbers 364 and then hardened. Consequently, even when a terminal of an external device repeatedly comes into contact with the separate insulating silicone rubbers 364, the shape change thereof are minimized by the protective resin 366, and a lifetime of the separate insulating silicone rubbers 364 is extended.

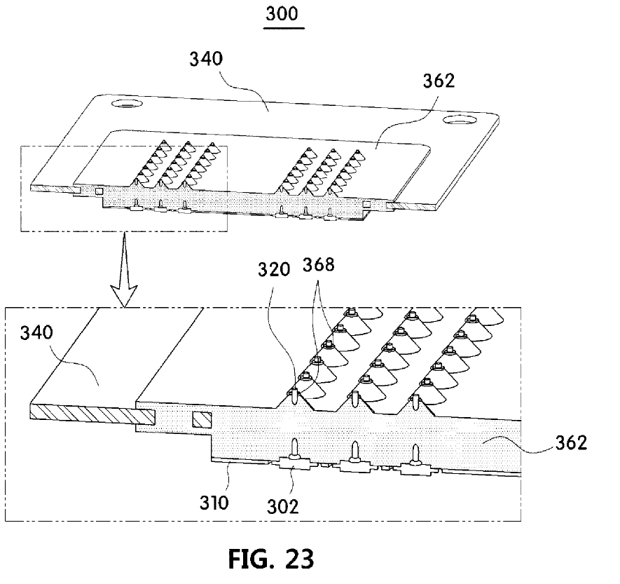

Referring to FIG. 23, a protective pad 368 may be inserted into at least a portion of the surfaces of the separate insulating silicone rubbers 364 of the present disclosure. The protective pad 368 may be disposed at an uppermost end of the separate insulating silicone rubbers 364. The protective pad 368 may primarily perform a function of preventing a shape change of the separate insulating silicone rubbers 364 in a region at which the separate insulating silicone rubbers 364 come into contact with the terminal of the external device and preventing the separate insulating silicone rubbers 364 from being collapsed. When manufactured with a conductive material, the protective pad 368 may simultaneously perform a function of forming electrical contact with the terminal of the external device together with the conductive wires 320.

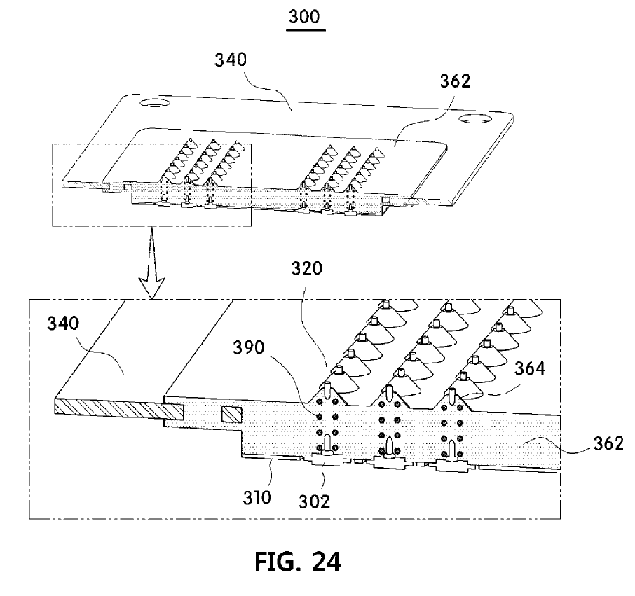

Referring to FIG. 24, the separate insulating silicone rubbers 364 of the present disclosure may further include a coil type protective spring 390 around the conductive wires 320. Particularly, the protective spring 390 may prevent the separate insulating silicone rubbers 364 from being collapsed due to an impact of an external force and provide elasticity upon impact.

Referring to FIG. 25, the present disclosure may further include a contact guide film 370 configured to guide the terminal of the test device so that the terminal of the test device is not mismatched with connector portions of the conductive wires 320. At the contact guide film 370, contact holes 372 in which the separate insulating silicone rubbers 364 are respectively disposed are formed in one-to-one correspondence with the conductive wires 320. As a result, the contact guide film 370 prevents the terminal from being arbitrarily detached after the terminal comes into contact with the connector portions of the conductive wires 320.

The contact guide film 370 may be composed of a PI film having a small thickness and excellent wear resistance. However, embodiments are not necessarily limited thereto, and the contact guide film 370 may be manufactured with any plastic film such as a PPS film, a PEEK film, a PPA film, a PSU film, a PES film, a PEI film, and a PEN film.

In this way, the upper surface of the single insulating silicone rubber 362 may be covered using the contact guide film 370, and the upper surfaces of the separate insulating silicone rubbers 364 may be exposed. The contact holes 372 in which the separate insulating silicone rubbers 364 are respectively accommodated are further included in the contact guide film 370. The conductive wires 320 being exposed may be exposed to the outside of the contact holes 372.

Hereinafter, a method of manufacturing a test socket according to the present disclosure will be described with reference to the drawings.

Referring to FIG. 26, the PCB 310 is prepared. A plurality of bonding pads 302 are formed on the PCB 310. The bonding pads 302 may be manufactured by electroplating or electrolessly plating Cu. The conductive wires 320 are bonded on the PCB 310. The conductive wires 320 come into contact with the bonding pads 302. The conductive wires 320 may be formed of a single wire or multiple wires. The conductive wires 320 may provide elasticity to an external device coming into contact therewith through a shape change.

A FPCB is used as the PCB 310. It is easy to design a circuit pattern using a screen printing or photolithography process and workability is high when the FPCB is used. Particularly, the FPCB is the most suitable for a continuous roll-to-roll process. For example, when a flexible circuit film in which a circuit pattern is printed at one surface or both surfaces is used as the PCB 310, a continuous process is possible.

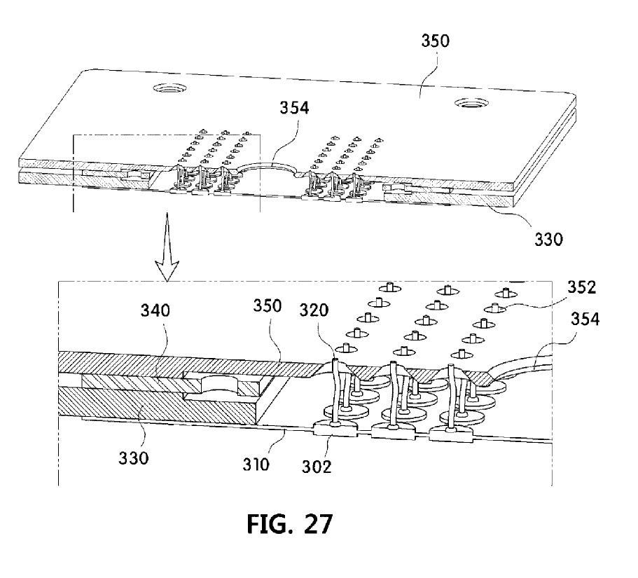

Referring to FIG. 27, a jig assembly is assembled. First, a space 330 having edges through which the PCB 310 is exposed is mounted at an upper surface of the PCB 310. Then, the base 340 through which the PCB 310 is exposed is mounted on the space 330. Lastly, a jig 350 configured to cover the PCB 310 is installed on the base 340. Align holes (no reference numerals) configured to vertically align the jig assembly may be formed at corners of each of the space 330, the base 340, and the jig 350. A plurality of wire holes 352 are formed with a predetermined rule at the jig 350.

In this way, the jig assembly is used as a mold for injecting a liquid silicone rubber 360 which will be described below. For example, in addition to the PCB 310 disposed at the bottom, the jig assembly includes the space 330 mounted at the upper surface of the PCB 310, the base 340 mounted at an upper surface of the space 330, and the jig 350 mounted on the base 340. Here, the space 330 and the base 340 are quadrangular frames each having a window, and the bonding pads 302 are exposed through the window. Conversely, the jig 350 covers the bonding pads 302. The jig 350 includes, at a center thereof, a silicone injection hole 354 through which silicone is injected, which will be described below.

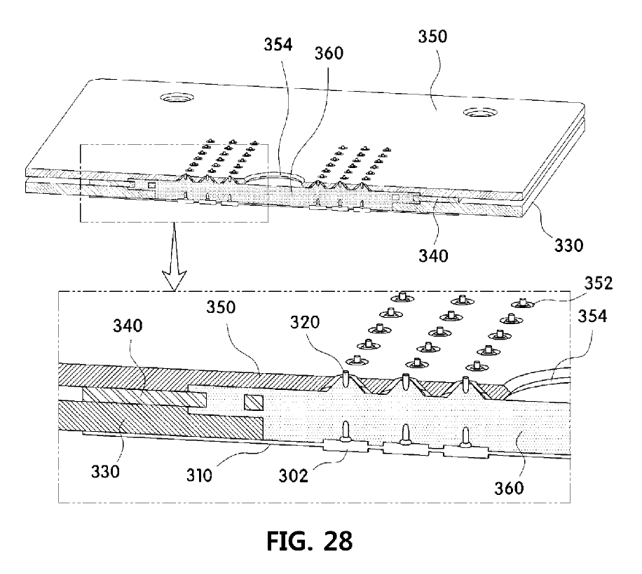

Referring to FIG. 28, the liquid silicone rubber 360 is injected into the jig assembly. In the jig assembly of the present disclosure, the PCB 310 is disposed at the bottom, and the jig 350 including the silicone injection hole 354 is disposed at the uppermost portion so that the liquid silicone rubber 360 is injected through the jig 350. Here, one should be careful not to deform the conductive wires 320 while the liquid silicone rubber 360 is being injected. A silicone injection pressure is adjusted according to a hardness of silicone and a material or thickness of the conductive wires 320. Particularly, because the plurality of wire holes 352 are formed at the upper surface of the jig 350, silicone may overflow when one fails to adjust a pressure of injecting the liquid silicone rubber 360.

Referring again to FIG. 19, the jig 350 at the top is removed. When the jig 350 is removed, the liquid silicone rubber 360 may not be sufficiently hardened as much as the insulating silicone rubbers 362 and 364. Here, an additional hardening process may be further performed. Then, the space is removed. The base 340 is kept without change to maintain an overall form.

Referring again to FIG. 25, the contact guide film 370 is attached. The contact guide film 370 configured to protect the single insulating silicone rubber 362 and facilitate contact between the terminal of the test device and the conductive wires 320 is attached to an upper surface of the single insulating silicone rubber 362 from which the jig 350 is removed.

Hereinafter, a preferable fourth embodiment of a test socket according to the present disclosure having the above-described configuration will be described in detail with reference to the accompanying drawings.

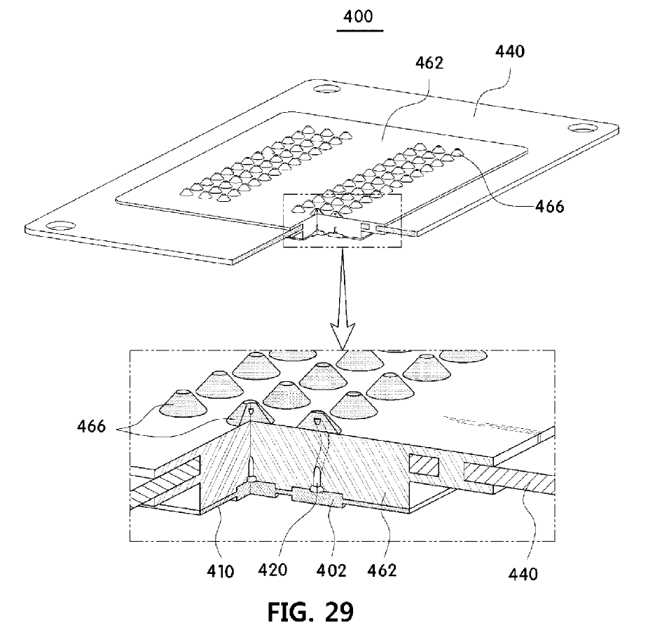

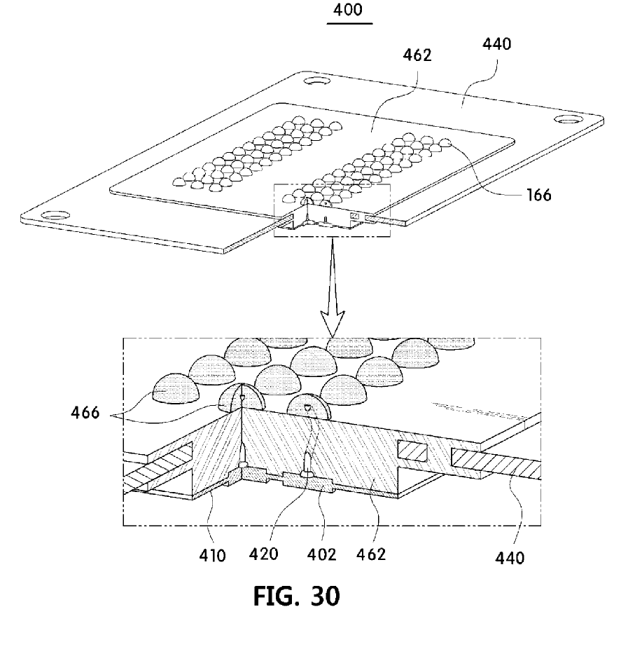

A partially cut-away perspective view of a configuration of a test socket including a cone type separate conductive silicone rubber according to an embodiment of the present disclosure is illustrated in FIG. 29, and a partially cut-away perspective view of a configuration of a test socket including an arch type separate conductive silicone rubber according to another embodiment of the present disclosure is illustrated in FIG. 30.

Referring to FIG. 29, a test socket 400 of the present disclosure includes a PCB 410, a plurality of conductive wires 420 connected using a bonding pad 402 on the PCB 410, a single insulating silicone rubber 462 having the conductive wires 420 arranged at a constant interval in the horizontal direction and extending in a vertical direction, and separate conductive silicone rubbers 466 formed on the single insulating silicone rubber 462 and each having a portion of the conductive wire 420 inserted thereinto such that the conductive wire 420 is pressed and conductively connected to the separate conductive silicone rubber 466. The test socket 400 may further include a base 440 supported to partially overlap an edge of the insulating silicone rubber 462.

A rigid PCB in which a circuit is configured by printing Cu on an epoxy resin or phenol resin or a FPCB in which various circuit patterns are formed on a PI film having high flexibility by using Cu, Au, or other conductive materials may be used as the PCB 410.

The conductive wires 420 pass through the single insulating silicone rubber 462 and are inserted into the separate conductive silicone rubbers 466 such that the conductive wires 420 form electrical contact with a terminal of an external device through the separate conductive silicone rubbers 466. One end of each of the conductive wires 420 is connected to the bonding pad 402 through a bonding joining portion, and the other end thereof is connected to the separate conductive silicone rubber 466.

The conductive wires 420 may be plated with Au or Ni, which is conductive. While testing a semiconductor device, even when the test socket 400 is pressed by the semiconductor device, for an impact thereof to be absorbed while an electrical connection is maintained, the conductive wires 420 are not necessarily manufactured in a linear shape and may be formed in a zigzag shape or a helical spring shape, thereby absorbing a physical impact and minimizing damage.

The single insulating silicone rubber 462 is not limited to a silicone rubber and may be any material having a predetermined elasticity. Examples of the single insulating silicone rubber 462 may include a heat-resistant polymer material having a crosslinking structure, such as a polybutadiene rubber, a urethane rubber, a natural rubber, a polyisoprene rubber, and other elastic rubbers. The single insulating silicone rubber 462 is formed in a rectangular shape having an extremely wide area in comparison to a thickness thereof, and the base 440 is a quadrangular frame which surrounds edges of the rectangular insulating silicone rubber 462.

In this way, the separate conductive silicone rubbers 466 coming into contact with the terminal of the test device are further included at one surface of the single insulating silicone rubber 462. To reinforce a contact characteristic between the conductive wires 420 and the terminal of the test device, the separate conductive silicone rubbers 466 may perform a function of elastically supporting the conductive wires 420 inserted thereinto from the side and the top.

For example, for more accurate contact with the test device upon contact with the test device, the separate conductive silicone rubbers 466 may protrude in a corn shape or a trapezoidal shape whose diameter gradually decreases from the single insulating silicone rubber 462.

Referring to FIG. 30, cases in which the separate conductive silicone rubbers 466 are formed in a dome shape, an arch shape, or the like may also be considered. In addition, to ensure independence of the separate conductive silicone rubbers 466, a shape change may be limited to only a simple pillar shape.

Here, the separate conductive silicone rubbers 466 are unstructured conductive connectors composed of a silicone-based rubber resin in which conductive powder and a platinum (Pt) catalyst are included. Here, the Pt catalyst accelerates hardening, but because electrical resistance may be increased when a composition ratio of the Pt catalyst is excessively large, a proper mixing ratio should be selected for the Pt catalyst.

The above-mentioned conductive powder of the unstructured conductive connectors may include a single metal such as silver (Ag), iron (Fe), Ni, or cobalt (Co) having magnetism or two or more metals therefrom.

In comparison to a conductive connector in which conductive particles are magnetically aligned in a silicon-based rubber resin, the separate conductive silicone rubber 466 is manufactured by an extremely simpler process, and a yield is improved.

For example, in comparison to a magnetic alignment process in which, in a conductive connector used as a conductive silicone rubber, conductive particles are aligned in the silicone rubber by a pressing conductive silicone rubber method, and, for this, a magnetic field is applied to align the conductive particles, a manufacturing process may be simplified, and a manufacturing cost may be reduced.

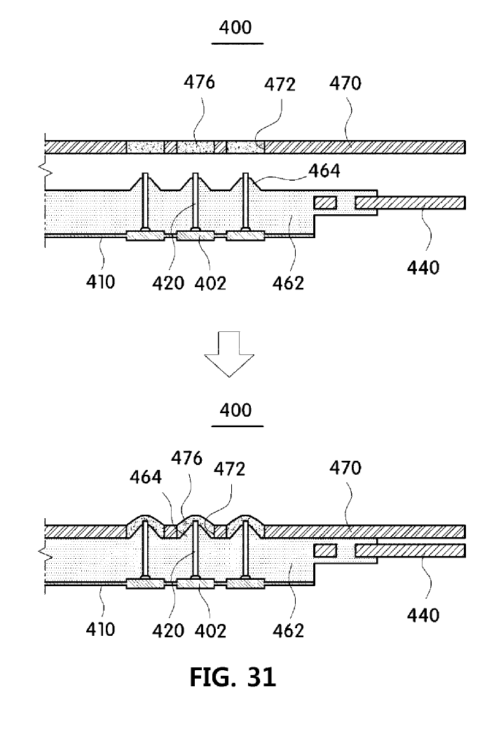

A cross-sectional view of a configuration of a test socket in which a pressing conductive silicone rubber is included in a contact guide film according to still another embodiment of the present disclosure is illustrated in FIG. 31. Referring to FIG. 31, the present disclosure may further include a contact guide film 470 configured to guide the terminal of the test device so that the terminal of the test device is not mismatched with connector portions of the conductive wires 420.

For example, the test socket 400 of the present disclosure may include the PCB 410, the plurality of conductive wires 420 connected using the bonding pad 402 on the PCB 410, the single insulating silicone rubber 462 disposed on the PCB 410, having the conductive wires 420 arranged at a constant interval in the horizontal direction and extending in a vertical direction, a plurality of separate insulating silicone rubbers 464 integrally formed with the single insulating silicone rubber 462 and configured to independently support the conductive wires 420, and the above-mentioned contact guide film 470.

At the contact guide film 470, contact holes 472 in which the separate insulating silicone rubbers 464 are respectively disposed are formed in one-to-one correspondence with the conductive wires 420. As a result, the contact guide film 470 prevents the terminal from being arbitrarily detached after the terminal comes into contact with the connector portions of the conductive wires 420.

The contact guide film 470 may be composed of a PI film having a small thickness and excellent wear resistance. However, embodiments are not necessarily limited thereto, and the contact guide film 470 may be manufactured with any plastic film such as a PPS film, a PEEK film, a PPA film, a PSU film, a PES film, a PEI film, and a PEN film.

In this way, the upper surface of the single insulating silicone rubber 462 may be covered using the contact guide film 470, and the upper surfaces of the separate insulating silicone rubbers 464 may be exposed. Here, the above-mentioned contact holes 472 are filled with a pressing conductive silicone rubber 474.

As described above, the pressing conductive silicone rubber 474 is an unstructured conductive connector composed of a silicone-based rubber resin in which conductive powder and a Pt catalyst are included, and the conductive powder may include a single metal such as Ag, Fe, Ni, or Co having magnetism or two or more metals therefrom.

Hereinafter, a preferable fifth embodiment of a test socket according to the present disclosure having the above-described configuration will be described in detail with reference to the accompanying drawings.

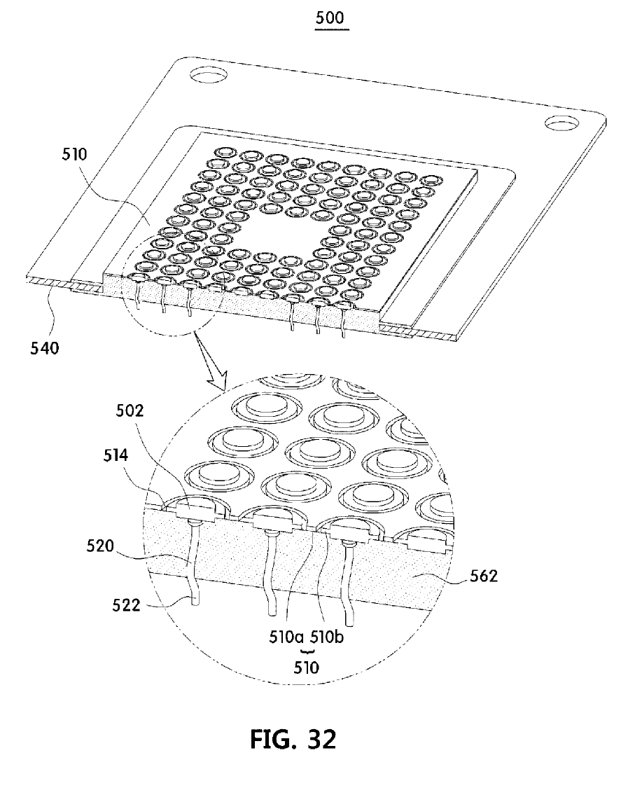

Referring to FIG. 32, a test socket 500 of the present disclosure includes a PCB 510 at which bonding pads 502 are formed, a conductive wire 520 wire-bonded on the bonding pads 502 and extending vertically therefrom, and an insulating silicone rubber 562 configured to elastically support the conductive wire 520 at one surface of the PCB 510. The test socket 500 may further include a base 540 supported to partially overlap an edge of the insulating silicone rubber 562.

The conductive wire 520 passes through the insulating silicone rubber 562 and protrudes and extends from an upper surface of the insulating silicone rubber 562. The conductive wire 520 forms a conductive connector 522 at the protruding and extending portion thereof.

Consequently, one end of the conductive wire 520 is connected to the bonding pad 502 through a bonding joining portion, and the other end thereof is exposed to the outside through the conductive connector 522.

Here, the bonding pad 502 is a portion coming in contact with a ball of a semiconductor device to be tested, and the conductive connector 522 is a portion coming in contact with a terminal of a test device which tests the semiconductor device to be tested.

A rigid PCB in which a circuit is configured by printing Cu on an epoxy resin or phenol resin or a FPCB in which various circuit patterns are formed on a PI film having high flexibility by using Cu, Au, or other conductive materials may be used as the PCB 510.

The conductive wire 520 may be plated with Ag or Ni, which is conductive. While testing a semiconductor device, even when the test socket 500 is pressed by the semiconductor device, for an impact thereof to be absorbed while an electrical connection is maintained, the conductive wire 520 is not necessarily manufactured in a linear shape.

The insulating silicone rubber 562 is not limited to a silicone rubber and may be any material having a predetermined elasticity. Examples of the insulating silicone rubber 562 may include a heat-resistant polymer material having a crosslinking structure, such as a polybutadiene rubber, a urethane rubber, a natural rubber, a polyisoprene rubber, and other elastic rubbers.

The insulating silicone rubber 562 is formed in a rectangular shape having an extremely wide area in comparison to a thickness thereof, and the base 540 is a quadrangular frame which surrounds edges of the rectangular insulating silicone rubber 562. The base 540 is formed in the shape of a quadrangular frame, and a portion thereof at an inner side of a window is inserted into the insulating silicone rubber 562.

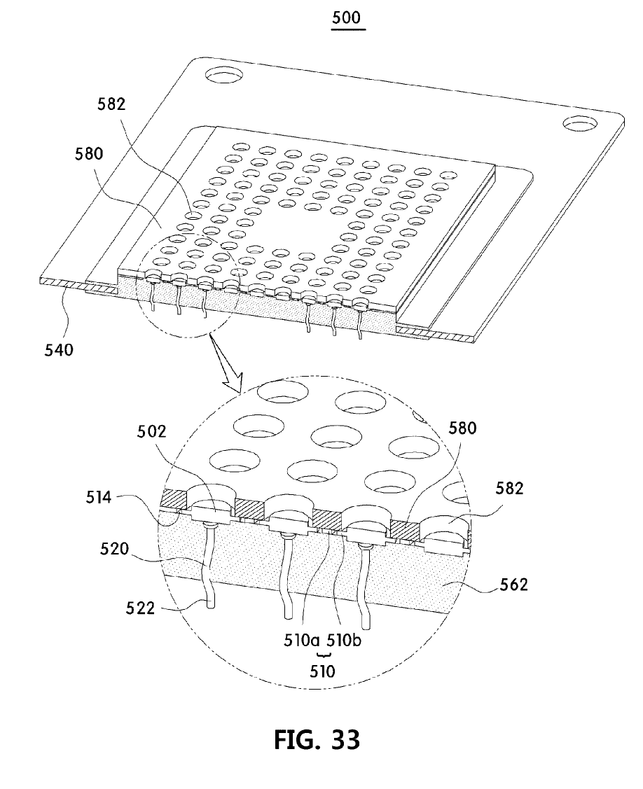

Referring to FIG. 33, the present disclosure may further include a ball guide film 580 configured to guide the ball of the semiconductor device so that the ball of the semiconductor device is not mismatched with the bonding pad 502. At the ball guide film 580, a pad hole 582 in which the bonding pad 502 is disposed and the ball is seated is formed in one-to-one correspondence with the bonding pad 502. As a result, the ball guide film 580 prevents the ball from being arbitrarily detached after the ball comes into contact with the bonding pad 502.

The ball guide film 580 may be composed of a PI film having a small thickness and excellent wear resistance. However, embodiments are not necessarily limited thereto, and the ball guide film 580 may be manufactured with any plastic film such as a PPS film, a PEEK film, a PPA film, a PSU film, a PES film, a PEI film, and a PEN film.

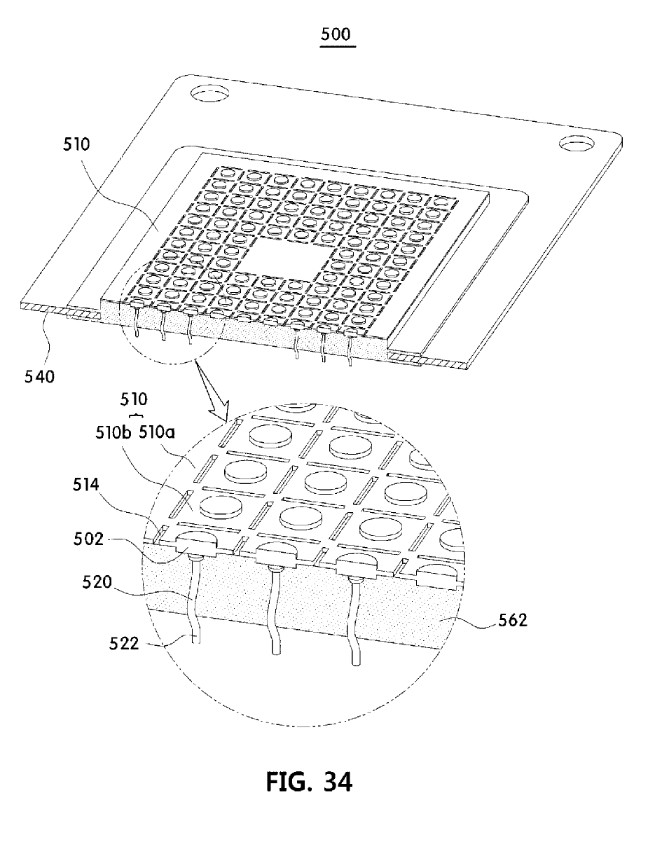

Referring to FIG. 34, the PCB 510 may include a PCB body 510a joined to and supported by the insulating silicone rubber 562, and a plurality of PCB lands 510b including the bonding pads 502 and completely or incompletely independent from the PCB body 510a so that mutual interference between the bonding pads 502 is minimized. A differentiation between the PCB body 510a and the PCB lands 510b is not absolute, and the PCB body 510a may be maintained between the PCB lands 510b.

The PCB lands 510b are incompletely independent from the PCB body 510a. By the PCB lands 510b being partially spaced apart from the PCB body 510a through recesses 514, the PCB lands 510b and the PCB body 510a are connected to each other, and the PCB lands 510b are still affected by the PCB body 510a or neighboring PCB lands 510b.

The recesses 514 are formed by removing portions of the PCB 510 through a laser cutting process or etching process and extend in a linear or curved manner. In this way, the PCB body 510a and the PCB lands 510b are partitioned by the recesses 514 and constitute an island.

Here, despite laser cutting or etching, the recesses 514 may pass through the PCB 510, and the insulating silicone rubber 562 is exposed in some cases. However, by forming the recesses 514 in the form of a groove not passing through the PCB 510, the insulating silicone rubber 562 may not be exposed.

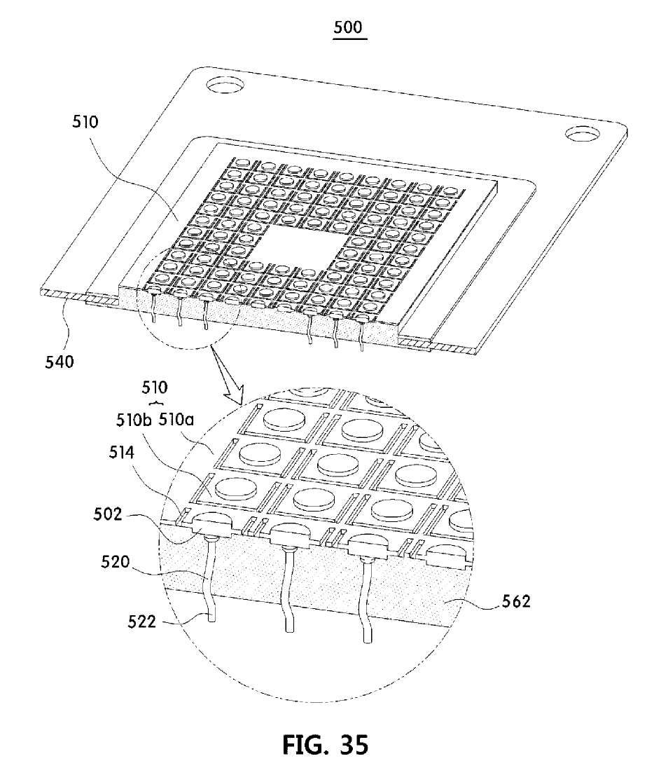

The recesses 514 may be discontinuously formed on the horizontal plane of the PCB 510 in all of four directions, front, rear, left, and right directions, of the bonding pads 502 as illustrated in FIG. 34 or may be continuously formed in three of the four directions, front, rear, left, and right directions, as illustrated in FIG. 35.

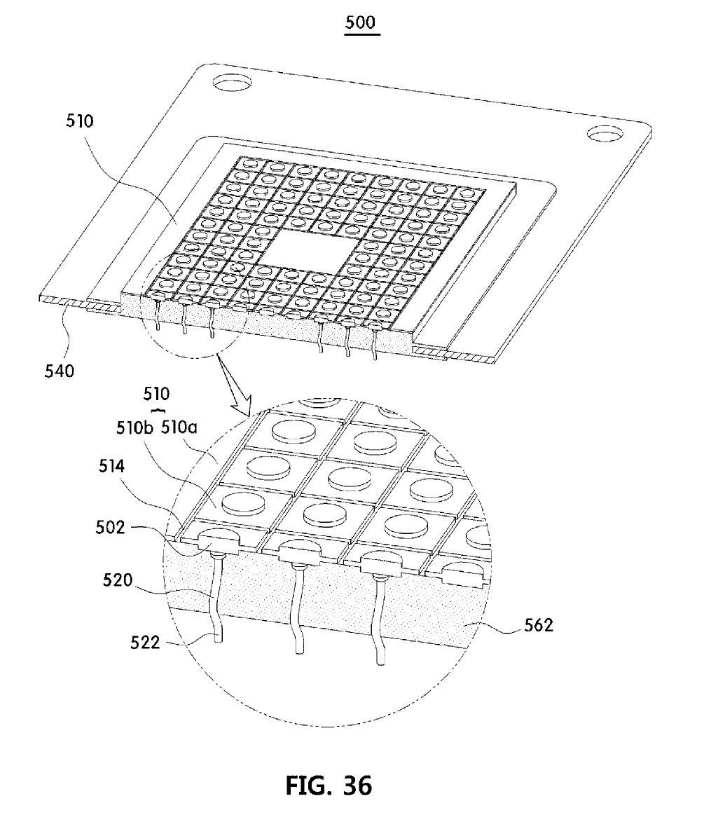

Referring to FIG. 36, the PCB lands 510b are completely independent from the PCB body 510a. By the PCB lands 510b being completely spaced apart from the PCB body 510a through the recesses 514, the PCB lands 510b and the PCB body 510a are connected only through the insulating silicone rubber 562, and the PCB lands 510b are not affected by the PCB body 510a through the PCB 510.

However, because the center of the PCB body 510a is disconnected from the a peripheral portion of the PCB body 510a due to the PCB lands 510b, the center of the PCB body 510a and the peripheral portion of the PCB body 510a may be joined and supported only by the insulating silicone rubber 562, and overall durability may be deteriorated.

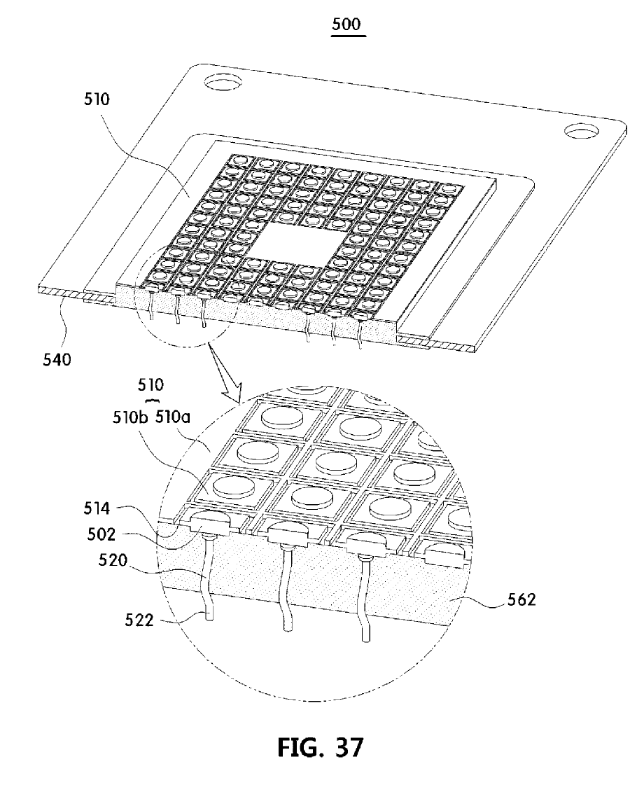

Referring to FIG. 37, the PCB lands 510b being completely spaced apart from the PCB body 510a through the recesses 514, the PCB lands 510a and the PCB body 510a being connected only through the insulating silicone rubber 562, and the PCB lands 510b not being affected by the PCB body 510a through the PCB 510 are the same as the above embodiment.

However, because the center and the peripheral portion of the PCB body 510a are integrally connected as itself except for the PCB lands 510b, the center of the PCB body 510a and the peripheral portion of the PCB body 510b are joined and supported by the insulating silicone rubber 562 and durability is increased such that a function of protecting the insulating silicone rubber 562 may be fully performed.

Referring again to FIG. 33, the ball guide film 580 configured to cover the PCB 510 may perform a function of simultaneously reinforcing a contact characteristic through the pad hole 582 and protecting the PCB lands 510b. For example, the ball guide film 580 has at least a width or an area relatively narrower or smaller than that of the PCB lands 510b and prevents the PCB lands 510b from being arbitrarily detached.

Hereinafter, a preferable sixth embodiment of a test socket according to the present disclosure having the above-described configuration will be described in detail with reference to the accompanying drawings.

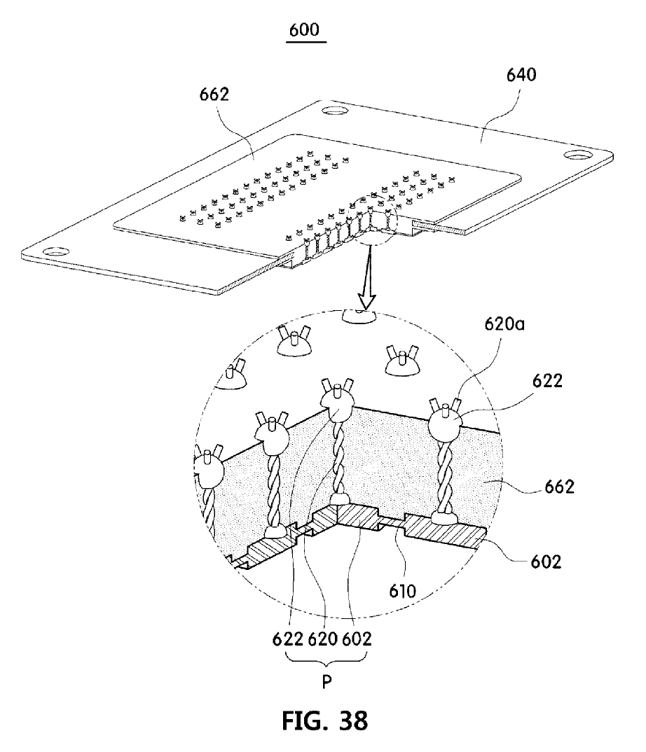

Referring to FIG. 38, a test socket 600 of the present disclosure includes a PCB 610, multiple-wire complexes P installed at a predetermined interval on the PCB, and an insulating silicone rubber 662 at which the multiple wire complexes P are elastically supported. The test socket 600 may further include a base 640 supported to partially overlap an edge of the insulating silicone rubber 662.

A rigid PCB in which a circuit is configured by printing Cu on an epoxy resin or phenol resin or a FPCB in which various circuit patterns are formed on a PI film having high flexibility by using Cu, Au, or other conductive materials may be used as the PCB 610.

The multiple wire complex P may include two or more multiple assembled wires. However, in the present disclosure, a multiple wire complex P including three assembled conductive wires, which is structurally the most stable, will be described as an example.

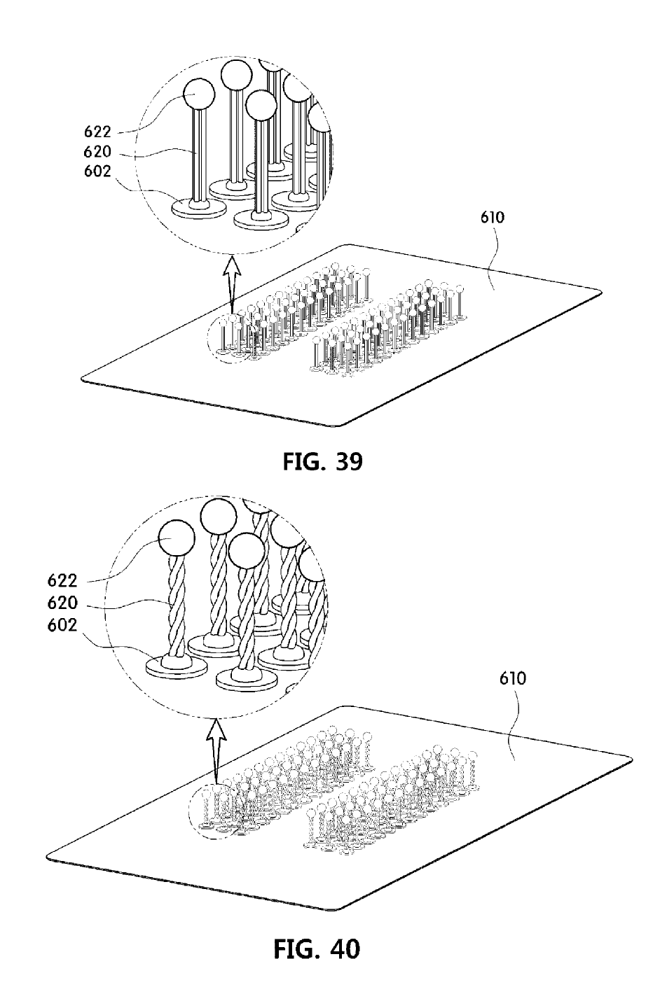

Referring to FIG. 39, the multiple wire complex P includes three assembled conductive wires 620 extending in a normal line direction of the PCB 610, a bonding pad 602 connected to one ends of the conductive wires 620, and a solder ball 622 connected to the other ends of the conductive wires 620. The three assembled conductive wires 620 may be repeatedly wire-bonded as twisted wires or wire-bonded at once as a single wire.

Referring to FIG. 40, the three assembled conductive wires 620 may be twisted in a constant direction. Alternatively, some of the conductive wires having an electrical conduction function may be bonded in a linear manner, and some of the conductive wires having a mechanical support function may be bonded in a twisted manner.

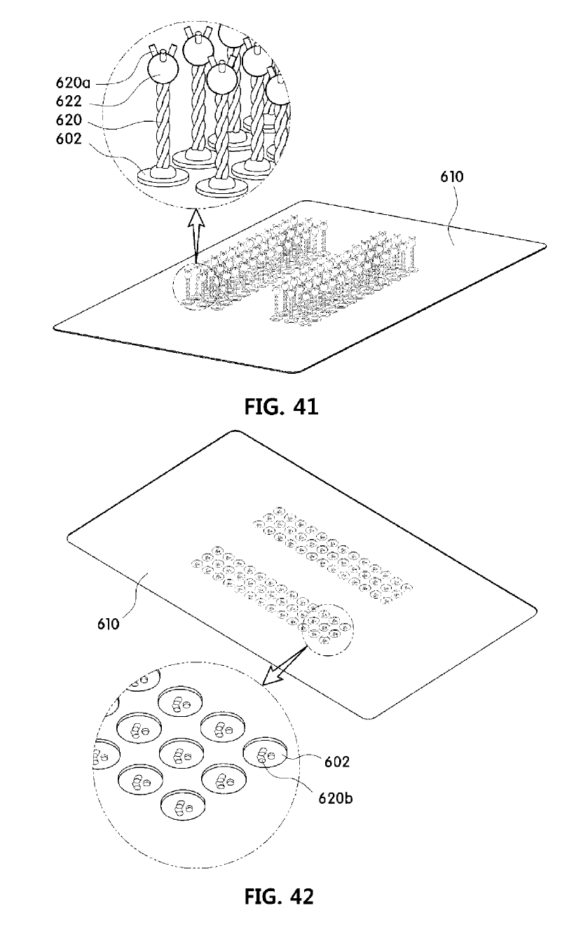

Referring to FIG. 41, portions of the three assembled conductive wires 620 may pass through the solder ball 622 and be exposed, thereby forming solder-side conductive connectors 620a.

Such conductive connectors 620a take a crown form in which the conductive connectors 620a are disposed at a predetermined interval. When the conductive connectors 620a take the crown form, each of the conductive connectors 620a is tilted at a predetermined angle with respect to the normal line of the PCB 610 and form edge contact with a terminal of a test device, a bump of a semiconductor device, or the like.

For example, although an external terminal such as a conductive ball or a bump is formed with a metal alloy having excellent electrical conductivity, a natural oxide film is applied on a surface thereof during a forming process thereof. Such a natural oxide film is formed at a terminal contact surface such that the natural oxide film interferes with electrical conduction with the conductive connectors 620a and degrades electrical performance. However, edge portions of the conductive connectors 620a come into contact with the external terminal such that the natural oxide film is broken at a boundary therebetween, and an overall contact characteristic is reinforced.

Referring to FIG. 42, portions of three assembled conductive wires (not illustrated) may pass through the bonding pad 602 and be exposed, thereby forming pad-side conductive connectors 620b. Likewise, the conductive connectors 620b are provided in the crown form while the conductive connectors 620b are maintained at an interval at which a triangular shape is formed.

Although not illustrated in the drawings, a coil spring may be inserted around the conductive wires 620, and mechanical strengths of the conductive wires 620 may be further complemented. The conductive wires 620 may be plated with Au or Ni, which is conductive. While testing a semiconductor device, even when the test socket 600 is pressed by the semiconductor device, for an impact thereof to be absorbed, the conductive wires 620 may be formed in a zigzag shape.

The three assembled conductive wires 620 twisted in this way may provide a vertical compressive force and a tensile force, thereby absorbing an impact and minimizing damage. Because the above three assembled conductive wires 620 support the insulating silicone rubber 662 as themselves, a collapse of the silicone rubber may be prevented. The number of the above assembled conductive wires 620 may be four or more according to a required degree of elasticity.

Here, at least one or more of the assembled conductive wires 620 performs a function of transmitting a high speed electrical signal. At least another one ore more of the conductive wires performs a function of complementing a mechanical strength. In this way, due to assembled conductive wires transmitting a plurality of electrical signals, even when any one of the assembled conductive wires is disconnected, a function of the disconnected conductive wire can be realized by the remaining conductive wires. Thus, electrical performance may be maintained without change, and a lifecycle of a product may be extended.

However, when the form of the assembled conductive wires 620 is changed into a twisted form, because the length of the conductive wires 620 themselves may be increased, electrical resistance may be increased. Consequently, a diameter of each of the conductive wires 620 may be reduced proportional to the increase in the length thereof.

To reinforce a contact characteristic of the conductive wires 620 and assist formation thereof through reflow, the solder ball 622 may be composed of lead (Pb) or tin (Sn). In this way, the solder ball 622 performs a function of integrally connecting the assembled conductive wires 620 through reflow.

The multiple wire complexes P are arranged at a predetermined interval on the insulating silicone rubber 662. As necessary, a separate silicone rubber in a trapezoidal shape or arch shape may be further formed on an upper surface of the single insulating silicone rubber 662 to reinforce the contact characteristic and independently support the wires. The insulating silicone rubber 662 is not limited to a silicone rubber and may be any material having a predetermined elasticity.

Hereinafter, a preferable seventh embodiment of a test socket according to the present disclosure having the above-described configuration will be described in detail with reference to the accompanying drawings.

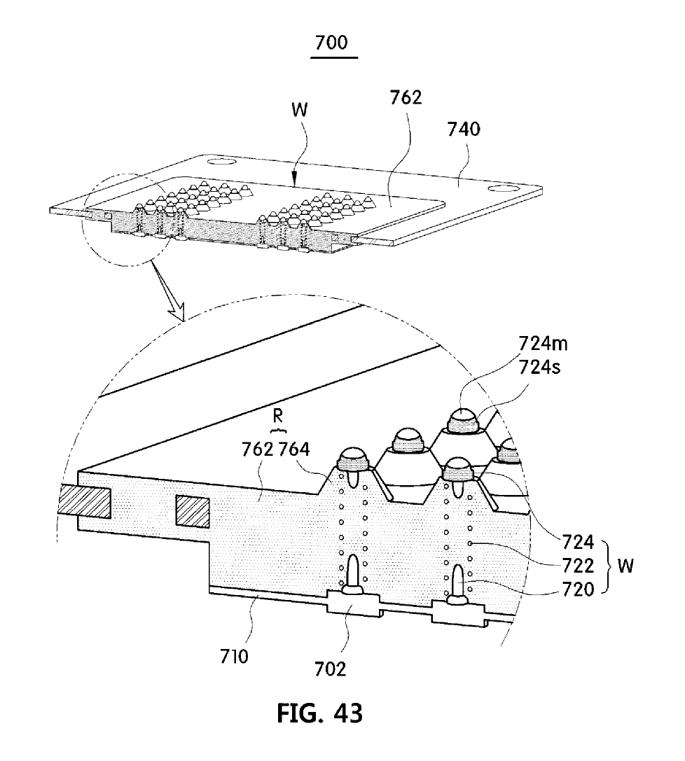

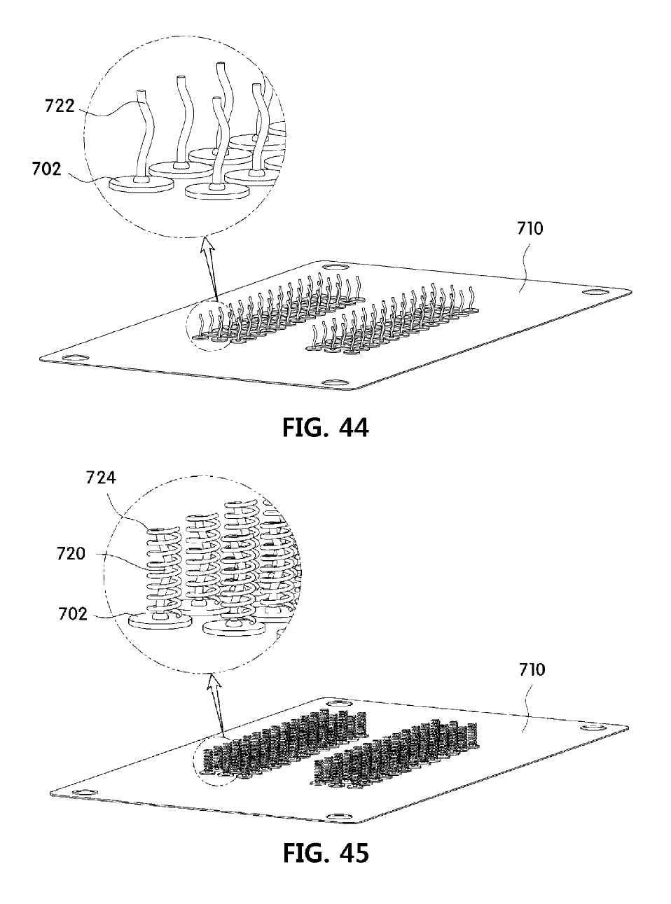

Referring to FIG. 43, a test socket 700 of the present disclosure includes a PCB 710 including bonding pads 702, conductive wire bonding structure W wire-bonded to the bonding pads 702s on the PCB, and an insulating silicone elastic structure R in which the conductive wire bonding structures W are inserted and elastically supported. The test socket 700 may further include a base 740 supported to partially overlap an edge of the insulating silicone elastic structure R.

A rigid PCB in which a circuit is configured by printing Cu on an epoxy resin or phenol resin or a FPCB in which various circuit patterns are formed on a PI film having high flexibility by using Cu, Au, or other conductive materials may be used as the PCB 710.

The conductive wire bonding structure W includes a conductive wire 720 extending vertically, a coil spring 722 configured to elastically support the conductive wire 720 near the conductive wire 720, and a conductive ball 724 configured to connect the conductive wire 720 to an external device at the top of the conductive wire 720.

The conductive wire 720 may be plated with Au or nickel, which is conductive. While testing a semiconductor device, even when the test socket 700 is pressed by the semiconductor device, for an impact thereof to be absorbed while an electrical connection is maintained, the conductive wire 720 is not necessarily manufactured in a linear shape and may be formed in a zigzag shape or a helical spring shape, thereby absorbing a physical impact and minimizing damage.

Such a conductive wire 720 is a semiconductor device bonding wire (for example, a thickness thereof is about 24 to 75 μm), and because the conductive wire 720 is formed of a material such as Au, Ni, Ag, Pt, aluminum (Al), Cu, or the like which is conductive, the conductive wire 720 has high electrical conductivity but has a disadvantage in that durability for maintaining elasticity even with repeated experiments is weak. Consequently, deformation of the conductive wire 720 due to repeated collisions or, particularly, a problem that the contact characteristic is very weak is required to be complemented.

Thus, the present disclosure uses the coil spring 722 to reinforce an elastic force and uses the conductive ball 724 to reinforce the contact characteristic. That is, conductive wire bonding is realized using the conductive ball 724 in the form of a metal core solder ball.

Although the coil spring 722 vertically provides a compressive force or tensile force, the coil spring 722 is also inserted into a silicone rubber to prevent collapse of the silicone rubber. A diameter, a length, a pitch interval, or the like of the coil spring 722 may be designed in various ways in consideration of a required degree of elasticity.

However, because the length of the coil spring 722 is increased due to the coil spring 722 having a larger diameter than that of the bonding conductive wire 720 or having a helical shape, there is a disadvantage in that electrical resistance is naturally increased. Consequently, rather than a function of electrically connecting a test device and a semiconductor device, the coil spring 722 mostly performs a function of complementing an elastic force between the test device and the semiconductor device.

As a result, the conductive wire 720 secures the shortest possible distance (for example, 1 mm or less) and becomes a transmission path of an electrical signal and, particularly, transmits a high speed signal to improve test reliability. Conversely, the coil spring 722 is not suitable as an electrical signal transmission path due to high impedance deviation and secures a mechanical elastic force, thereby extending a product lifetime despite repeated tests.

The conductive ball 724 reinforces the contact characteristic of the conductive wire 720. Referring to FIG. 43, the conductive ball 724 includes a metal core 724m at a center and a solder dummy 724s at a peripheral portion. The metal core 724m has a characteristic in that a shape thereof is maintained despite reflow, and the solder dummy 724s has a characteristic in that a shape thereof is changed due to reflow.

The metal core 724m may be composed solely of Cu. Alternatively, the metal core 724m may be composed of a combination of Cu at a center and Ag at a peripheral portion. The solder dummy 724s may include Pb or Sn having a relatively low melting point.

The conductive ball 724 has the double structure including the metal core 724m and the solder dummy 724s as above due to the following reason. After a reflow process, although the metal core 724m maintains its shape without change despite reflow and serves as the conductive ball 724, the solder dummy 724s is melted due to reflow and is unable to maintain its original shape. As illustrated in the drawing, it can be recognized that the solder dummy 724s is flowed down due to having Pb or Sn as major components.

Consequently, the solder dummy 724s, as itself, performs a function of coupling the conductive wire 720 and the metal core 724m and a function of coupling the coil spring 722 and the metal core 724m by reflow. Furthermore, the solder dummy 724s performs a function of integrally coupling the conductive wire 720 and the coil spring 722.

The insulating silicone elastic structure R includes a single insulating silicone rubber 762 on which the conductive wire bonding structures W are arranged at a predetermined interval and separate insulating silicone rubber 764 integrally formed with the insulating silicone rubber and configured to independently support the conductive wire bonding structures W.

The single insulating silicone rubber 762 and the separate insulating silicone rubber 764 are not limited to a silicone rubber and may be any material having a predetermined elasticity. Examples of the single insulating silicone rubber 762 and the separate insulating silicone rubber 764 may include a heat-resistant polymer material having a crosslinking structure, such as a polybutadiene rubber, a urethane rubber, a natural rubber, a polyisoprene rubber, and other elastic rubbers. The single insulating silicone rubber 762 is formed in a rectangular shape having an extremely wide area in comparison to a thickness thereof.

In this way, the separate insulating silicone rubber 764 coming into contact with the terminal of the test device is further included at one surface of the single insulating silicone rubber 762. To reinforce a contact characteristic between the conductive wire 720 and the terminal of the test device, the separate insulating silicone rubber 764 may perform a function of elastically supporting the conductive wire 720 inserted thereinto from the side.

For example, for more accurate contact with the test device upon contact with the test device, the separate insulating silicone rubber 764 may protrude in a corn shape or a trapezoidal shape whose diameter gradually decreases from the single insulating silicone rubber 762. The separate insulating silicone rubber 764 may protrude in a dome shape or an arch shape.

Hereinafter, a method of manufacturing a test socket according to the present disclosure will be described with reference to the drawings.

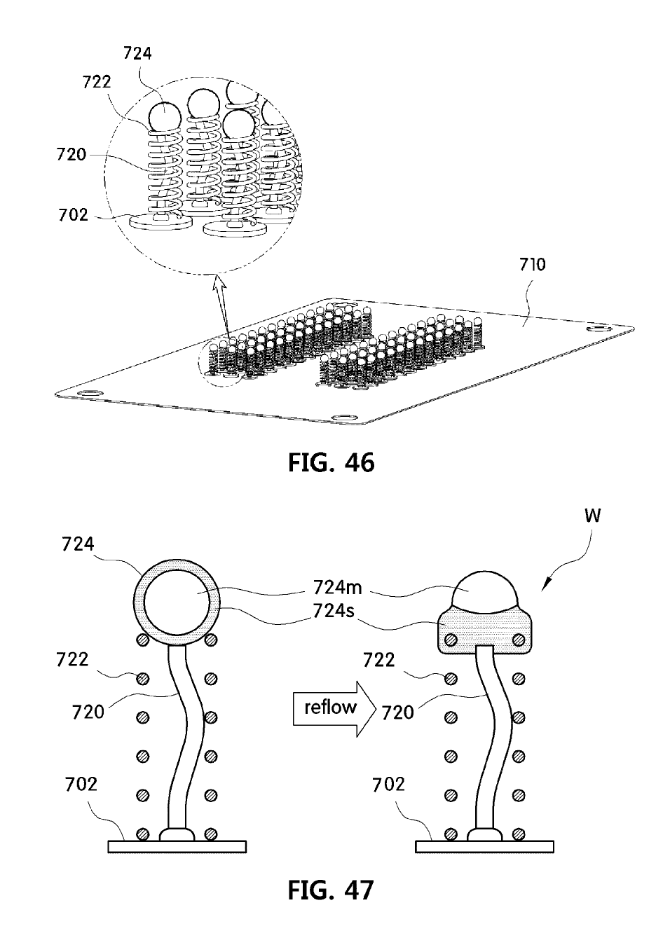

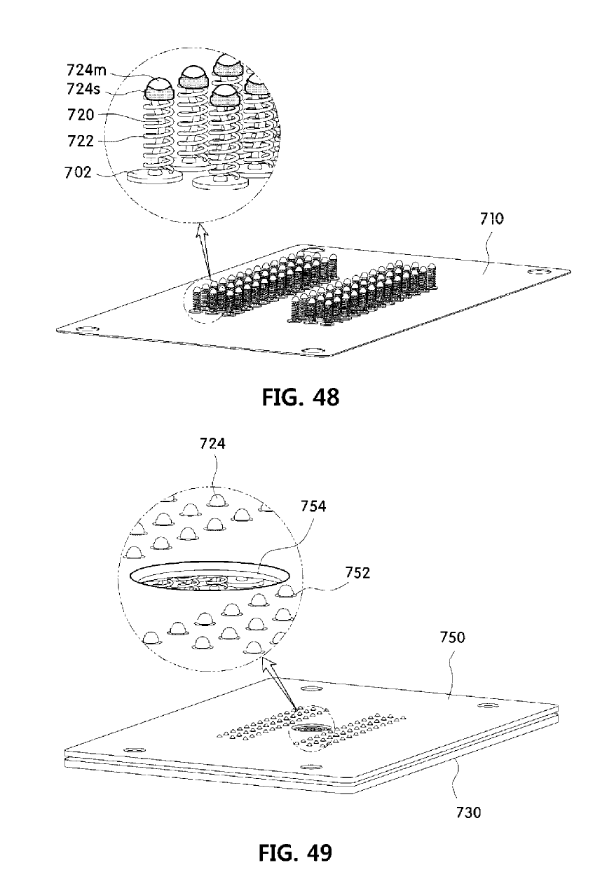

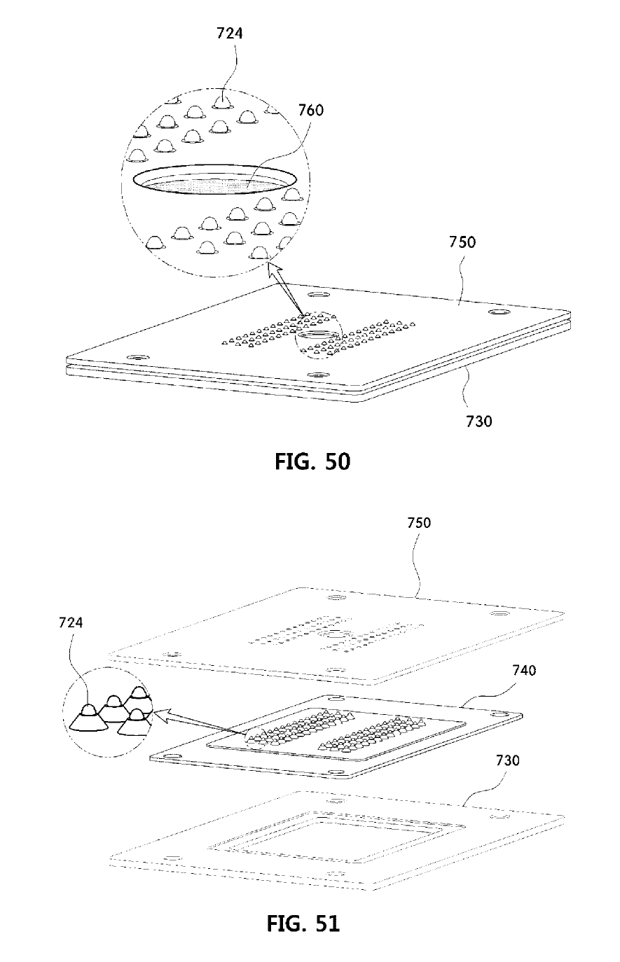

A method of manufacturing a conductive wire bonding structure and a test socket according to the present disclosure is illustrated in FIGS. 45 to 51. A wire bonding process is illustrated in FIG. 45, a coil spring insertion process is illustrated in FIG. 46, a conductive ball mounting process is illustrated in FIG. 47, a conductive ball reflow process is illustrated in FIG. 48, a jig assembly assembling process is illustrated in FIG. 49, a silicone injection process is illustrated in FIG. 50, and a jig assembly removal process is illustrated in FIG. 51.

Referring to FIG. 45, the PCB 710 is prepared. The plurality of bonding pads 702 are formed on the PCB 710. The bonding pads 702 may be manufactured by electroplating or electrolessly plating Cu. The conductive wire 720 is bonded on the PCB 710. The conductive wire 720 comes into contact with the bonding pad 702. The conductive wire 720 may be formed of a single wire or multiple wires. The conductive wire 720 may provide elasticity to an external device coming into contact therewith through a shape change as illustrated in the drawing.

Referring to FIG. 46, the coil spring 722 is inserted into the conductive wire 720. Here, a height of the coil spring 722 is preferably not smaller than that of the conductive wire 720 for the conductive ball 724 to be stably disposed on the coil spring 722 in a conductive ball seating process, which will be described below. When necessary, an adhesive may be used to fix the coil spring 722 on the bonding pad 702.

Referring to FIG. 47, the conductive ball 724 is seated above the coil spring 722 and the conductive wire 720. The conductive ball 724 includes the metal core 724m at the center and the solder dummy 724s at the peripheral portion.

Referring to FIG. 48, the conductive ball 724 is reflowed at a predetermined temperature at which at least the solder dummy 724s is at a melting point or higher. At this temperature, a spherical shape of the metal core 724m is maintained without change, and the solder dummy 724s is melted. The molten solder dummy 724s solders the metal core 724m to each of the conductive wire 720 and the coil spring 722.

Referring to FIG. 49, a jig assembly is assembled. First, a space 730 having edges through which the PCB 710 is exposed is mounted at an upper surface of the PCB 710. Then, the base through which the PCB 710 is exposed is mounted on the space 730. Lastly, a jig 750 configured to cover the PCB 710 is installed on the base 740. A plurality of wire holes 752 are formed with a predetermined rule at the jig 750.

In this way, the jig assembly is used as a mold for injecting a liquid silicone rubber 760 which will be described below. For example, in addition to the PCB 710 disposed at the bottom, the jig assembly includes the space 730 mounted at the upper surface of the PCB 710, the base 740 mounted at an upper surface of the space 730, and the jig 750 mounted on the base 740. The jig 750 includes, at a center thereof, a silicone injection hole 754 through which silicone is injected, which will be described below.

Referring to FIG. 50, the liquid silicone rubber 760 is injected into the jig assembly. In the jig assembly of the present disclosure, the PCB 710 is disposed at the bottom, and the jig 750 including the silicone injection hole 754 is disposed at the uppermost portion so that the liquid silicone rubber 760 is injected through the jig 750. Here, one should be careful not to deform the conductive wire 720 while the liquid silicone rubber 760 is being injected.

Referring again to FIG. 51, the jig 750 at the top is removed. When the jig 750 is removed, in a case in which the liquid silicone rubber 760 is not sufficiently hardened as much as the insulating silicone rubbers 762 and 764, an additional hardening process may be further performed. Then, the space is removed. The base 740 is kept without change to maintain an overall form.

Hereinafter, a preferable eighth embodiment of a test socket according to the present disclosure having the above-described configuration will be described in detail with reference to the accompanying drawings.

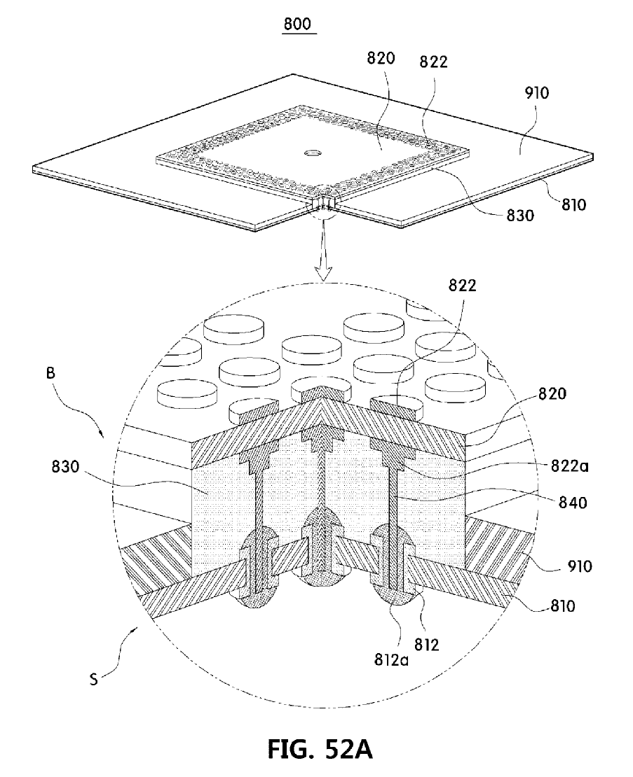

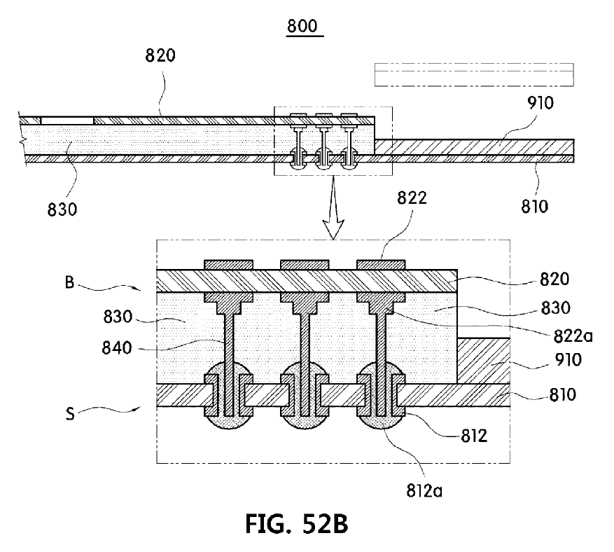

Referring to FIGS. 52A and 52B, a test socket 800 of the present disclosure includes a solder FPCB film 810 on which a solder pad 812 is formed, a bonding FPCB film 820 on which a bonding pad 822 is formed, an insulating silicone rubber 830 filled between the solder FPCB film 810 and the bonding FPCB film 820, a conductive wire 840 configured to connect the solder pad 812 and the bonding pad 822 between portions of the insulating silicone rubber 830, and a solder space 910 configured to support the test socket 800 at an upper portion of an edge of the solder FPCB film 810.

The solder pad 812 may be fastened to one end of the conductive wire 840 by a soldering joining portion 812a, and the bonding pad 822 may be fastened to the other end of the conductive wire 840 by a bonding joining portion 812a.

A solder-side substrate S is formed of the solder FPCB film 810 and the solder space 910, and the solder pad 812 is formed on the solder FPCB film 810 as described above. For example, various solder circuit patterns (not illustrated) are formed at the solder FPCB film 810, and the solder pad 812 electrically connects the solder circuit patterns to the outside. The soldering joining portion 812a formed on the solder pad 812 is also a portion coming into contact with a test device (not illustrated).

A bonding-side substrate B is formed of the bonding FPCB film 820 and a bonding space 920, and the bonding pad 822 is formed on the bonding FPCB film 820 as described above. For example, bonding circuit patterns in one-to-one or one-to-many correspondence with the solder circuit patterns may be formed at the bonding FPCB film 820, and the bonding circuit patterns may be electrically connected to the outside through the bonding pad 822. The bonding pad 822 is a portion connected to the conductive wire 840 by a bonding joining portion 822a and coming into contact with a semiconductor device (not illustrated).

A rigid PCB in which a circuit is configured by printing Cu on an epoxy resin or phenol resin or a FPCB in which various circuit patterns are formed on a PI film having high flexibility by using Cu, Au, or other conductive materials may be used as the solder FPCB film 810 and the bonding FPCB film 820.

The soldering joining portion 812a and the bonding joining portion 822a are electrically connected through the conductive wire 840. The conductive wire 840 may be plated with Au or Ni, which is conductive. The conductive wire 840 connects the solder pad 812 and the bonding pad 822 vertically or at a slant between the solder-side FPCB substrate S and the bonding-side FPCB substrate B.

While testing a semiconductor device, even when the test socket 800 is pressed by the semiconductor device, for an impact thereof to be absorbed while an electrical connection is maintained, the conductive wire 840 is not necessarily manufactured in a linear shape. For example, the conductive wire 840 may be formed in a zigzag shape or a helical spring shape, thereby absorbing a physical impact and minimizing damage.

The insulating silicone rubber 830 is not limited to a silicone rubber and may be any material having a predetermined elasticity. Examples of the insulating silicone rubber 830 may include a heat-resistant polymer material having a crosslinking structure, such as a polybutadiene rubber, a urethane rubber, a natural rubber, a polyisoprene rubber, and other elastic rubbers.

Hereinafter, a method of manufacturing a test socket according to the present disclosure will be described with reference to the drawings.

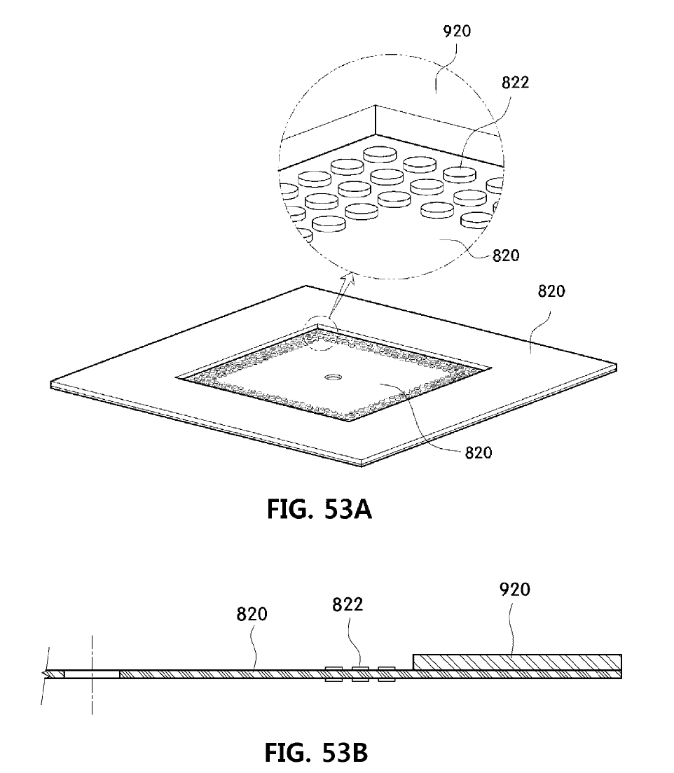

Perspective views and cross-sectional views of a method of manufacturing a test socket according to the present disclosure are illustrated in FIGS. 53A to 58B.

Referring to FIGS. 53A and 53B, the bonding-side substrate B is prepared.

A bonding space 920 having edges through which the bonding FPCB film 820 is exposed is further disposed on the bonding FPCB film 820. An injection hole (no reference numeral) for silicone injection is formed at a center of the bonding FPCB film 820. The bonding pad 822 is formed on the bonding FPCB film 820. The bonding pad 822 may be manufactured by electroplating or electrolessly plating Cu.

A FPCB is used as the bonding FPCB film 820. It is easy to design a circuit pattern using a screen printing or photolithography process and workability is high when the FPCB is used. Particularly, the FPCB is the most suitable for a continuous roll-to-roll process. When a flexible circuit film in which a circuit pattern is printed at one surface or both surfaces is used as the bonding-side substrate B, a continuous process is possible.

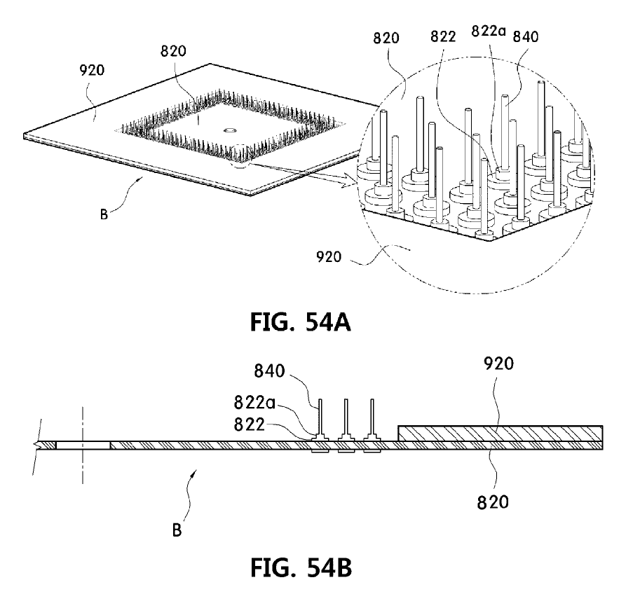

Referring to FIGS. 54A and 54B, the conductive wire 840 is bonded on the bonding FPCB film 820.

The conductive wire 840 comes into contact with the bonding pad 822. In this way, the bonding joining portion 822a is formed. The conductive wire 840 may be formed of a single wire or multiple wires.

According to an embodiment of the present disclosure, after the bonding process, the conductive wire 840 may be primarily plated with Ni. Ni may have somewhat low conductivity, and in a case of a high-frequency wave, a signal may flow to a surface of Ni, and a characteristic thereof may be deteriorated. Thus, Au may be secondarily plated on Ni.

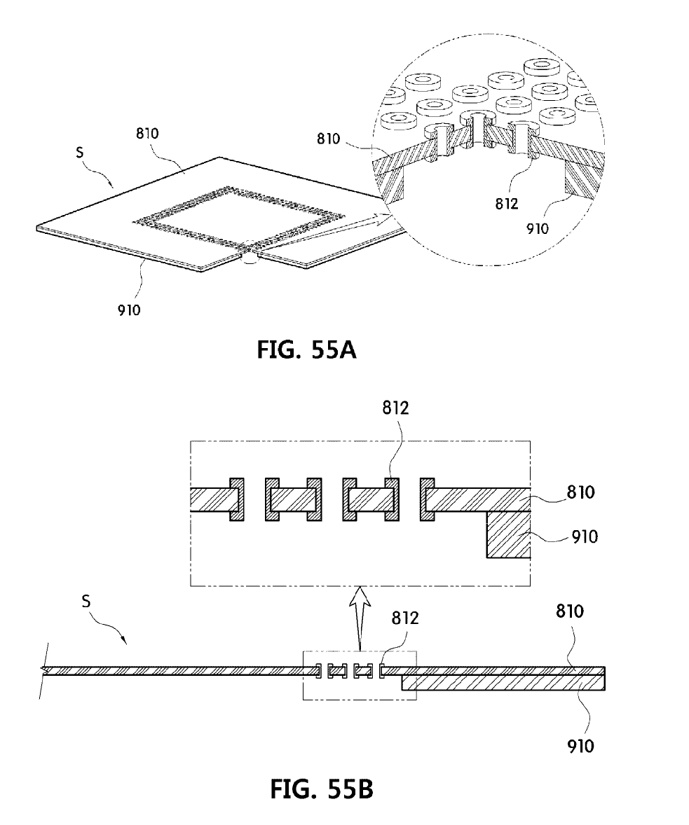

Referring to FIGS. 55A and 55B, the solder-side substrate S may be prepared on the bonding-side substrate B.

The solder space 910 having edges through which the solder FPCB film 810 is exposed is further disposed on the solder FPCB film 810. Like the bonding space 920, the solder space 910 is used as a mold for silicone injection, which will be described below. However, the solder space 910 still remains after a cutting process, which will be described below.

The solder pad 812 is formed on the solder FPCB film 810. The solder pad 812 may be manufactured by electrolessly plating Cu. A hole may be formed in the solder pad 812, and the conductive wire 840 may be inserted thereinto.

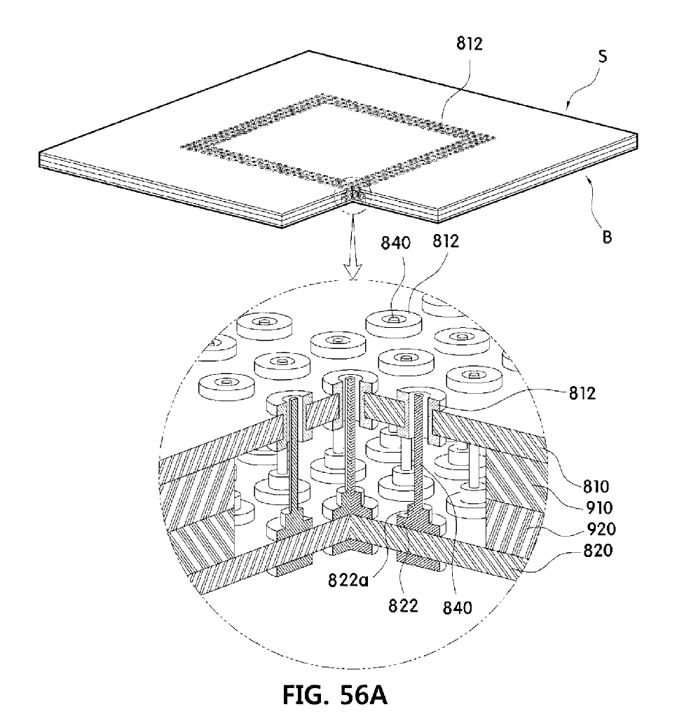

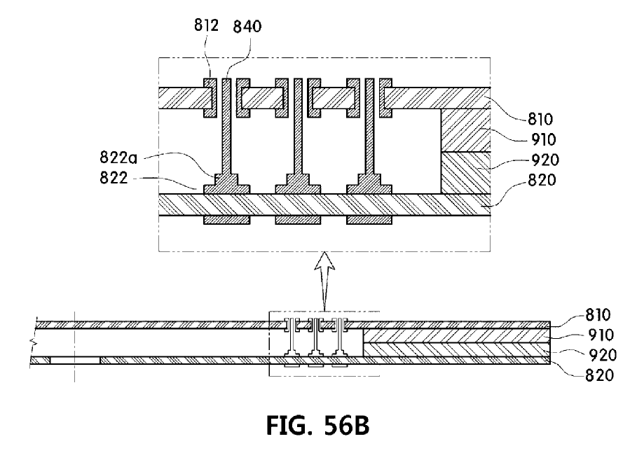

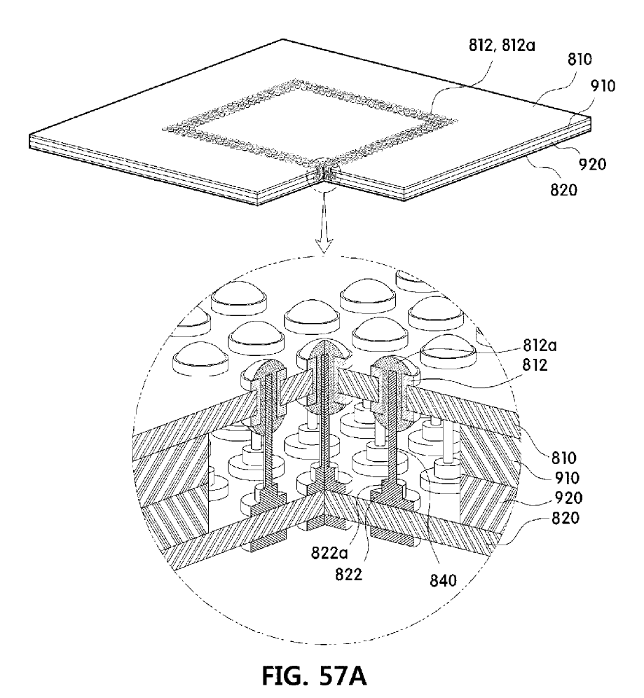

Referring to FIGS. 56A and 56B, the bonding-side substrate B and the solder-side substrate S are assembled.

The bonding-side substrate B and the solder-side substrate S are brought face to face to assemble the bonding-side substrate B and the solder-side substrate S. The bonding space 920 and the solder space 910 correspond to and come into contact with each other.

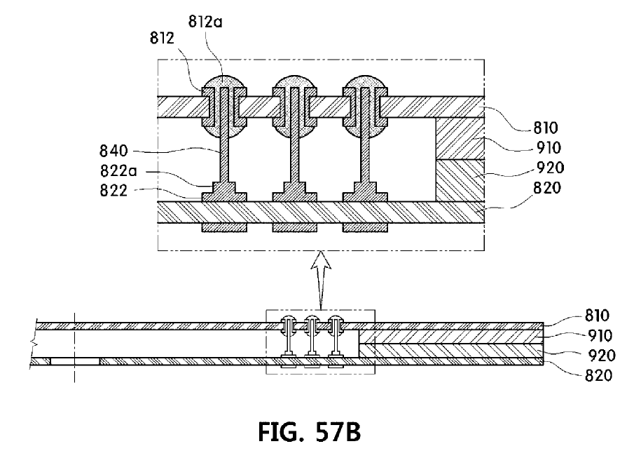

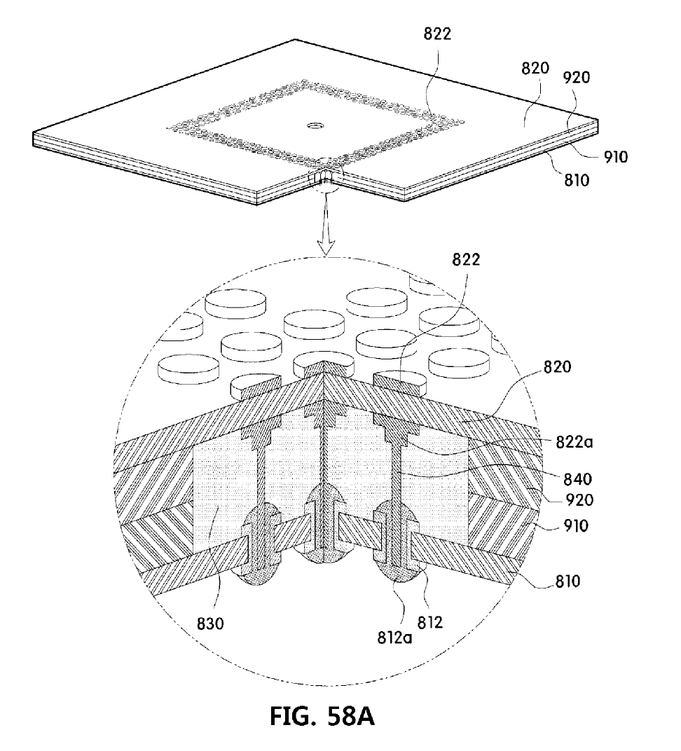

Referring to FIGS. 57A and 57B, the conductive wire 840 is soldered to the solder FPCB film 810.

A soldering process is performed while the conductive wire 840 is inserted into the hole of the bonding pad 822, and the soldering joining portion 812a is formed. Soldering may be performed by a robot soldering or dot soldering technique. Alternatively, soldering may be performed using a conductive adhesive. A reflow process may be further performed to maintain a height of the soldering joining portion 812a to be constant. After the soldering process, a cleaning process may be proceeded.

Here, a screen printing method of solder cream and a jet injection method of a solder paste will be described as the soldering process.

The soldering process may be performed by the screen printing method of solder cream.

Solder cream is applied on the bonding pad 822 using a screen mask. A screen mask having an opening at a portion corresponding to the hole of the bonding pad 822 is prepared. The screen mask is mounted on the solder FPCB film 810, and the opening is filled with the solder cream through screen printing.

The conductive wire 840 is inserted so that an end of the conductive wire 840 comes into contact with the solder cream. Here, by applying the solder cream and inserting the conductive wire 840, misalignment of the conductive wire 840 is prevented. The end of the conductive wire 840 may be fixed by the solder cream, and a yield of an assembly process may be improved.

The reflow soldering is performed until a height deviation of the solder cream is eliminated, and despite different sizes of the solder cream, a contact characteristic of the solder ball 812a becomes constant. That is, the solder cream is formed into the solder ball 812a having a semi-spherical shape through the reflow soldering process.

Particularly, a reason for performing the solder cream process as a preprocessing process before the soldering process in the present disclosure is as follows.

When the solder cream is applied before the conductive wire 840 is inserted into the hole of the bonding pad 822, a fastening force between the bonding pad 822 and the solder ball 812a completed while the alignment of the conductive wire 840 is not deformed or affected by the solder cream is reinforced. For example, when the end of the conductive wire 840 comes into contact with the pad during an alignment process, there is a problem in that the conductive wire 840 is bent. Here, because the solder cream does not have such contact, misalignment of the conductive wire 840 is prevented. In this way, deterioration of the solder ball may be prevented.

When the solder cream is applied using screen printing, the process may be simplified. For example, a screen mask having a predetermined opening is used. The opening is formed at a portion corresponding to the hole of the bonding pad 822. The screen mask is placed on the solder FPCB film 810. When the solder cream is applied on the mask and pushed, the opening is filled with the solder cream. When the mask is removed and then a reflow process is performed at a predetermined temperature, the hole of the bonding pad 822 is filled with the solder cream.

Even in this case, the reflow process serves to eliminate a height deviation of the solder cream. Even for solder cream not having the same size, a height deviation may be eliminated through reflow.

In the soldering process, the solder ball may be formed by a jet printing method.

A height deviation of a plurality of solder balls 812a may be eliminated by jet injection. The height deviation is caused because sizes of solder balls 812a formed by the soldering process are different. Here, the height deviation of the solder balls 812a worsens a contact characteristic between the solder ball 812a and an external terminal of a test device connected thereto.

Thus, in the case of the present disclosure, because the solder ball 812a is formed through jet injection, there is a characteristic in that the height of the solder ball 812a is adjusted to be constantly decreased regardless of the size thereof. When the reflow process is added thereto, the height deviation of the solder balls 812a is further eliminated.

In the case of jet injection, there is an advantage in that, even when a difference exists in viscosities of the solder paste, the size of the solder ball 812a being ejected by a dispenser is maintained to be constant when a jet injection speed is adjusted. For example, using a nozzle, the solder paste is jet-injected to the bonding pad 822 on which the solder ball 812a is to be formed.

The reflow process is performed. Such reflow may be proceeded in an oven at a temperature of 160° C. or higher. As described above, the reflow is proceeded until the height deviation of the solder balls 812a is eliminated.

Because a solder is provided by a non-contact method in a one drop falling (ODF) method described above, the misalignment of the conductive wire 840 is maximally suppressed. Consequently, the ODF method is a method of forming a sphere-like solder ball 812a at once without touching the end of the conductive wire 840.

Conversely, soldering is performed after the liquid silicone rubber 830, which will be described below, is first inserted and hardened in some cases. In such a case, soldering is performed by a one drop jetting method, and because the shape or form of the solder ball 812a is closer to a spherical shape, a contact characteristic between the solder ball 812a and an external terminal is reinforced.

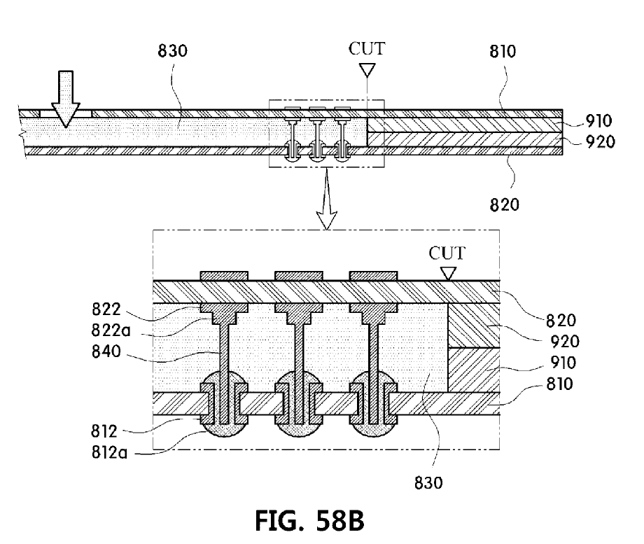

Referring to FIGS. 58A and 58B, silicone injection is performed.

Flipping is performed so that an injection hole in the bonding-side substrate B faces upward and is positioned above the solder-side substrate S. The liquid silicone rubber 830 is injected through the injection hole.

One should be careful not to deform the conductive wire 840 by the injection of the liquid silicone rubber 830. A silicone injection pressure should be adjusted according to a hardness of silicone and a material or thickness of the conductive wire 840.

A bent line (not illustrated) is disposed between the solder space 910 and the bonding space 920, and during the injection process, vacuum may be created inside the spaces for injection of the liquid silicone rubber 830.

Next, the bonding space 920 may be removed using laser. When the silicone is not completely hardened even after the cutting, an additional hardening process may be performed.

According to the above configuration of the present disclosure, while the bonding FPCB film and the solder FPCB film are vertically aligned using spaces, a conductive wire is bonded and soldered to each pad such that an electrical connection process of the pads at both sides may be continuously performed.

Because the bonding FPCB film at a lower portion is supported by the bonding space, and the solder FPCB film at an upper portion is supported by the solder space, a bonding failure or soldering failure due to twisting of the films themselves may be fundamentally prevented.

### INDUSTRIAL APPLICABILITY

The present disclosure can be used in a device for testing electrical characteristics of a semiconductor device before the semiconductor device is shipped.

1. A method of manufacturing a test socket, the method comprising:
preparing a printed circuit board (PCB) on which a bonding pad is disposed;
bonding a conductive wire on the bonding pad;
mounting, on an upper surface of the PCB, a space through which the bonding pad is exposed;
mounting, on an upper surface of the space, a base through which the bonding pad is exposed;
mounting, on an upper surface of the base, a jig which covers the bonding pad, and
injecting a liquid silicone rubber into a jig assembly by using the jig assembly as a mold, the jig assembly including the PCB, the space, the base, and the jig.

2. The method of claim 1, further comprising:
removing the jig when the liquid silicone rubber is hardened and becomes an insulating silicone rubber; and
removing the space.

3. The method of claim 2, wherein a silicone injection hole and a plurality of cone holes each provided for one corresponding conductive wire are formed in the jig.

4. The method of claim 3, wherein, when injecting the liquid silicone rubber into the jig assembly through the silicone injection hole, the injection pressure is adjusted to an extent that the liquid silicone rubber does not overflow through the cone holes.

5. The method of claim 2, further comprising attaching a cone guide film to an upper surface of the insulating silicone rubber from which the jig is removed,
wherein a connector hole configured to improve contact performance between the cone guide film and a terminal of a test device and prevent a detachment of the terminal after the contact is formed in the cone guide film.

6. The method of claim 2, further comprising attaching a ball guide film to a bottom surface of the PCB,
wherein a pad hole configured to improve contact performance between the ball guide film and a ball of a semiconductor device and prevent a detachment of the ball after the contact is formed in the ball guide film.

7. A jig assembly for manufacturing a test socket, the jig assembly comprising:
a printed circuit board (PCB) to which a conductive wire is bonded using a bonding pad;
a space mounted at an upper surface of the PCB and through which the bonding pad is exposed;
a base mounted at an upper surface of the space and through which the bonding pad is exposed; and
a jig mounted at an upper surface of the base and configured to cover the bonding pad.

8. The jig assembly of claim 7, wherein a silicone injection hole and a plurality of cone holes each provided for one corresponding conductive wire are formed in the jig.

9. The jig assembly of claim 8, wherein:
a diameter of the cone hole gradually decreases from bottom to top; and
the conductive wire passes through the cone hole and protrude to the outside.

10. The jig assembly of claim 7, wherein the space and the base are formed in the shape of a quadrangular frame having a window through which the bonding pad is exposed.

11-88. (canceled)
